(19) United States
(12) Patent Application Publication
(10) Pub. No.: US 2025/0301635 A1
(43) Pub. Date: Sep. 25, 2025

(54) MICROELECTRONIC DEVICES, AND RELATED MEMORY DEVICES AND ELECTRONIC SYSTEMS

(71) Applicant: Micron Technology, Inc., Boise, ID (US)

(72) Inventors: Fatma Arzum Simsek-Ege, Boise, ID (US); Yadhu Vamshi Sindhoor Reddy Vancha, Meridian, ID (US)

(21) Appl. No.: 19/060,304

(22) Filed: Feb. 21, 2025

Related U.S. Application Data
(60) Provisional application No. 63/569,059, filed on Mar. 22, 2024.

(51) Int. Cl. H10B 12/00; H01L 23/00; H01L 25/16; H10B 80/00; H10D 80/30

(52) U.S. Cl. CPC H10B 12/50; H01L 24/08; H01L 25/16; H10B 12/315; H10B 12/482; H10B 12/488; H10B 80/00; H10D 80/30; H01L 2224/08145; H01L 2924/1436

(57) ABSTRACT

A microelectronic device includes a memory array structure including array regions having volatile memory cells, a control circuitry structure vertically above and bonded to the memory array structure, and global routing tiers. The control circuitry structure includes control circuitry regions horizontally overlapping the array regions and comprising control logic circuitry coupled to the volatile memory cells. The global routing tiers vertically overlie the control logic circuitry. Some global routing tiers respectively include groups of global routing structures confined within horizontal areas of the control circuitry regions. The global routing structures of the groups horizontally extend in parallel in a first direction. Some other global routing tiers respectively include additional groups of global routing structures extending beyond the horizontal areas of the control circuitry regions. The global routing structures of the additional groups horizontally extend in parallel in a second direction orthogonal to the first direction.

### CROSS-REFERENCE TO RELATED APPLICATIONS

This application claims the benefit under 35 U.S.C. § 119(e) of U.S. Provisional Patent Application Ser. No. 63/569,059, filed Mar. 22, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices, and to related memory devices, electronic systems, and methods.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified, easier and less expensive to fabricate designs.

One example of a microelectronic device is a memory device. Memory devices are generally provided as internal integrated circuits in computers or other electronic devices. There are many types of memory devices including, but not limited to, volatile memory devices. One type of volatile memory device is a dynamic random-access memory (DRAM) device. A DRAM device may include a memory array including DRAM cells arranged rows extending in a first horizontal direction and columns extending in a second horizontal direction. In one design configuration, an individual DRAM cell includes an access device (e.g., a transistor) and a storage node device (e.g., a capacitor) electrically connected to the access device. The DRAM cells of a DRAM device are electrically accessible through digit line structures and word lines arranged along the rows and columns of the memory array and in electrical communication with control logic devices within a base control logic structure of the DRAM device.

Control logic devices within a base control logic structure underlying a memory array of a DRAM device have been used to control operations on the DRAM cells of the DRAM device. Control logic devices of the base control logic structure can be provided in electrical communication with digit line structures and word lines coupled to the DRAM cells by way of routing and contact structures. Unfortunately, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of a memory device, and/or improvements in the performance (e.g., faster memory cell ON/OFF speed, lower threshold switching voltage requirements, faster data transfer rates, lower power consumption) of the DRAM device.

### BRIEF DESCRIPTION OF THE DRAWINGS

FIG. 1 is a simplified, partial vertical cross-sectional view of a microelectronic device, in accordance with embodiments of the disclosure.

FIG. 2 is a simplified, partial schematic view of a memory array structure for the microelectronic device depicted in FIG. 1, in accordance with some embodiments of the disclosure.

FIG. 3 is a simplified, partial schematic view of a control circuitry structure for the microelectronic device depicted in FIG. 1, in accordance with some embodiments of the disclosure.

FIG. 4 is a diagram showing different vertical cross-sectional views of the microelectronic device collectively shown in FIGS. 1-3, taken about lines A-A and B-B depicted in FIGS. 2 and 3, in accordance with some embodiments of the disclosure.

FIG. 5 is a simplified, partial vertical cross-sectional view of a portion of the microelectronic device, in accordance with some embodiments of the disclosure.

FIGS. 6 and 7 are simplified, partial top-down views of the microelectronic device collectively shown in FIGS. 1 through 4, taken about dashed box C shown in FIG. 3, showing different feature configurations within a portion of the microelectronic device, in accordance with some embodiments of the disclosure.

FIGS. 8 and 9 are simplified, partial schematic views of a portion of the microelectronic device collectively shown in FIGS. 1 through 4, showing various routing structures at different vertical elevations within the microelectronic device, in accordance with some embodiments of the disclosure.

FIG. 10 is a simplified, partial schematic view of a different control circuitry structure for the microelectronic device depicted in FIG. 1, in accordance with some additional embodiments of the disclosure.

FIG. 11 is simplified, partial top-down view of the microelectronic device collectively depicted by way of FIGS. 1, 2, 4, and 10, taken about dashed box D shown in FIG. 11, showing different feature configurations within a portion of the microelectronic device, in accordance with some embodiments of the disclosure.

FIG. 12 is a simplified, partial schematic view of a portion of the microelectronic device collectively depicted by way of FIGS. 1, 2, 4, and 10, showing various routing structures at different vertical elevations within the microelectronic device, in accordance with some additional embodiments of the disclosure.

FIG. 13 is a simplified, partial schematic view of a portion of the microelectronic device collectively depicted by way of FIGS. 1, 2, 4, and 10, showing horizontal directional paths and horizontal orientations of different routing structures of the microelectronic device within different regions of the microelectronic device, in accordance with some embodiments of the disclosure.

FIG. 14 is a schematic block diagram of an electronic system, in accordance with an embodiment of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory; conventional non-volatile memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}AS_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓ N_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

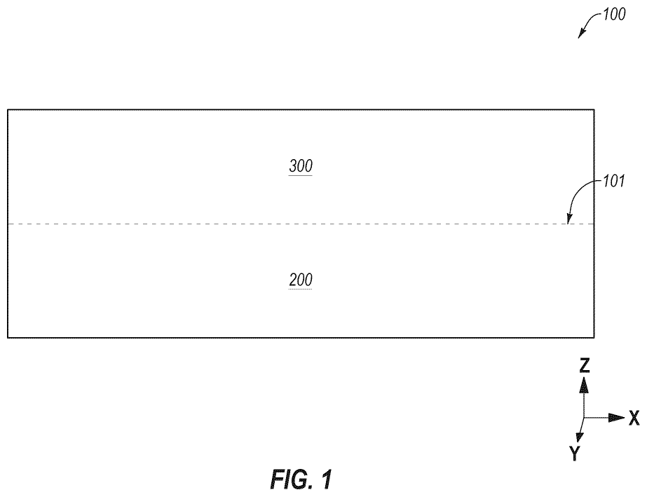

FIG. 1 is a simplified, partial longitudinal cross-sectional view of a microelectronic device 100 (e.g., a memory device, such as a DRAM device), in accordance with some embodiments of the disclosure. The microelectronic device 100 may include a memory array structure 200 (e.g., a memory array wafer), and a control circuitry structure 300 (e.g., a control circuitry wafer) vertically overlying and attached to the memory array structure 200. The memory array structure 200 may include one or more array(s) of memory cells (e.g., volatile memory cells, such as DRAM cells). At least a majority (e.g., substantially all) of the memory cells of the microelectronic device 100 may be located within the memory array structure 200 (and, hence, outside of the control circuitry structure 300). The control circuitry structure 300 may include control logic devices formed of and including complementary metal-oxide-semiconductor (CMOS) circuitry. At least a majority (e.g., substantially all) of the CMOS circuitry (and, hence, the control logic device) of the microelectronic device 100 may be located within the control circuitry structure 300 (and, hence, outside of the memory array structure 200). In addition, at least some of the CMOS circuitry may be positioned vertically above within horizontal areas of the array(s) of memory cells. Accordingly, the microelectronic device 100 may be considered to have a so-called “CMOS above array (CaA)” configuration.

In some embodiments, the control circuitry structure 300 is formed, at least in part, separate from the memory array structure 200; and then the control circuitry structure 300 is attached (e.g., bonded) to the memory array structure 200 at an interface 101 using dielectric-to-dielectric (e.g., oxide-to-oxide) bonding or a combination of dielectric-to-dielectric bonding and metal-to-metal bonding. For example, following the separate formations of the memory array structure 200 and the control circuitry structure 300, the control circuitry structure 300 and the memory array structure 200 may be brought into physical contact with one another at the interface 101, and then the resulting assembly may be exposed to a temperature greater than or equal to about 400° C. (e.g., within a range of from about 400° C. to about 800° C., greater than about 800° C.) to form oxide-to-oxide bonds between oxide dielectric material (e.g., SiOₓ, such as SiO₂) of the memory array structure 200 and additional oxide dielectric material (e.g., additional SiOₓ, such as additional SiO₂) of the control circuitry structure 300. In some embodiments, the oxide dielectric material of the memory array structure 200 and the additional oxide dielectric material of the control circuitry structure 300 are exposed to at least one temperature greater than about 800° C. to form oxide-to-oxide bonds between the oxide dielectric material of the memory array structure 200 and the additional oxide dielectric material of the control circuitry structure 300.

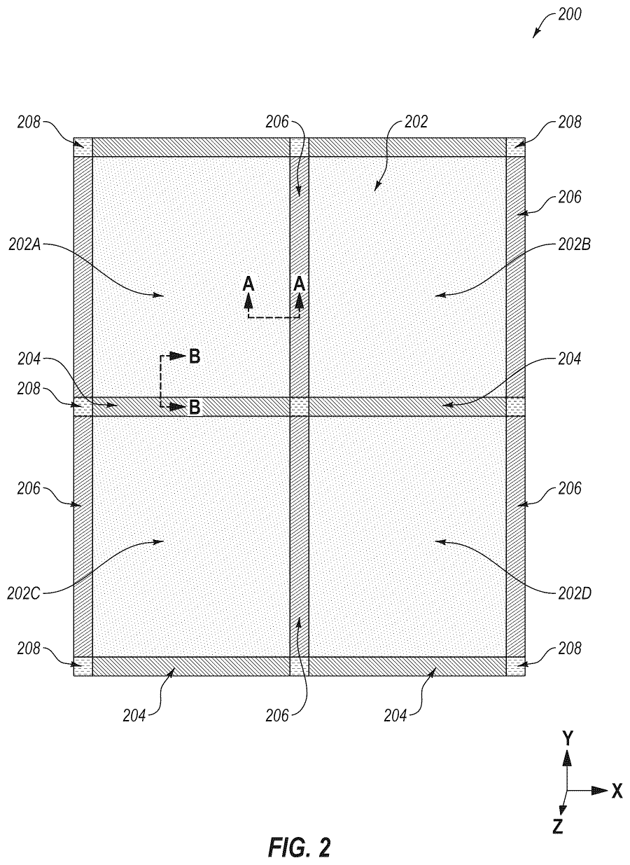

FIG. 2 is a simplified, partial schematic view of a portion of the memory array structure 200 of the microelectronic device 100 (FIG. 1), in accordance with some embodiments of the disclosure. FIG. 2 shows an arrangement of various circuitry of the memory array structure 200.

As shown in FIG. 2, the memory array structure 200 may include array regions 202, digit line exit regions 204 (also referred to as “digit line contact socket regions”) interposed between pairs of the array regions 202 horizontally neighboring one another in the Y-direction, word line exit regions 206 (also referred to as “word line contact socket regions”) interposed between additional pairs of the array regions 202 horizontally neighboring one another in the X-direction orthogonal to the Y-direction, and minigap regions 208 interposed between neighboring pairs of the digit line exit regions 204 in the X-direction and neighboring pairs of the word line exit regions 206 in the Y-direction. The array regions 202, the digit line exit regions 204, the word line exit regions 206, and the minigap regions 208 of the memory array structure 200 are each described in further detail below.

The array regions 202 of the memory array structure 200 may be regions of the memory array structure 200 having arrays of memory cells (e.g., arrays of volatile memory cells, such as arrays of DRAM cells) within horizontal areas thereof. The memory array structure 200 may be formed to include a desired quantity of the array regions 202. For clarity and ease of understanding of the drawings and related description, FIG. 2 depicts the memory array structure 200 as including four (4) array regions 202: a first array region 202A, a second array region 202B, a third array region 202C, and a fourth array region 202D. As shown in FIG. 2, the second array region 202B may horizontally neighbor the first array region 202A in the X-direction, and may horizontally neighbor the fourth array region 202D in the Y-direction; the third array region 202C may horizontally neighbor the first array region 202A in the Y-direction, and may horizontally neighbor the fourth array region 202D in the X-direction; and the fourth array region 202D may horizontally neighbor the third array region 202C in the X-direction, and may horizontally neighbor the second array region 202B in the Y-direction. However, the memory array structure 200 may include a different quantity of array regions 202. For example, the memory array structure 200 may be formed to include greater than four (4) array regions 202, such as greater than or equal to eight (8) array regions 202, greater than or equal to sixteen (16) array regions 202, greater than or equal to thirty-two (32) array regions 202, greater than or equal to sixty-four (64) array regions 202, greater than or equal to one hundred twenty-eight (128) array regions 202, greater than or equal to two hundred fifty-six (256) array regions 202, greater than or equal to five hundred twelve (512) array regions 202, or greater than or equal to one thousand twenty-four (1024) array regions 202.

As described in further detail below, the array regions 202 of the memory array structure 200 may individually include digit line structures (e.g., bit line structures, data line structures) extending the Y-direction, word line structures (e.g., access line structures) extending in the X-direction, and memory cells arranged at intersections of the digit line structures and the word line structures. Rows of the memory cells may be coupled to the word line structures, and columns of the memory cells may be coupled to the digit line structures. The memory cells within an individual array region 202 may, for example, comprise DRAM cells, resistive random-access memory (RRAM) cells, conductive bridge random-access memory (conductive bridge RAM) cells, magnetic random-access memory (MRAM) cells, phase change material (PCM) memory cells, phase change random-access memory (PCRAM) cells, spin-torque-transfer random-access memory (STTRAM) cells, oxygen vacancy-based memory cells, programmable conductor memory cells, or other types of memory cells. In some embodiments, the memory cells within an individual array region 202 of the memory array structure 200 are DRAM cells.

With continued reference to FIG. 2, the digit line exit regions 204 of the memory array structure 200 may comprise horizontal areas of the memory array structure 200 configured and positioned to have at least some of the digit line structures horizontally terminate therein. For an individual digit line exit region 204, at least some digit line structures operatively associated with the array regions 202 flanking (e.g., at opposing boundaries in the Y-direction) the digit line exit region 204 have ends within the horizontal boundaries of the digit line exit region 204. In addition, as described in further detail below, the digit line exit regions 204 may also be configured and positioned to include contact structures and routing structures within the horizontal boundaries thereof that are coupled to at least some of the digit line structures. Some of the contact structures within the digit line exit regions 204 may couple the digit line structures to control logic circuitry of control logic devices (e.g., sense amplifier (SA) devices, additional devices) within the control circuitry structure 300 (FIG. 1) of the microelectronic device 100 (FIG. 1). As shown in FIG. 2, in some embodiments, the digit line exit regions 204 horizontally extend in the X-direction, and are respectively horizontally interposed, in the Y-direction, between neighboring array regions 202. The digit line exit regions 204 may, for example, horizontally alternate with the array regions 202 in the Y-direction.

Still referring to FIG. 2, the word line exit regions 206 of the memory array structure 200 may comprise additional horizontal areas of the memory array structure 200 configured and positioned to have at least some of the word line structures horizontally terminate therein. For an individual word line exit region 206, at least some word line structures operatively associated with the array regions 202 flanking (e.g., at opposing boundaries in the X-direction) the word line exit region 206 have ends within the horizontal boundaries of the word line exit region 206. As described in further detail below, the word line exit regions 206 may also be configured and positioned to include contact structures and routing structures within the horizontal boundaries thereof that are coupled to the word line structures. Some of the contact structures within the word line exit regions 206 may couple the word line structures to control logic circuitry of additional control logic devices (e.g., sub-word line driver (SWD) devices, additional devices) within the control circuitry structure 300 (FIG. 1) of the microelectronic device 100 (FIG. 1). As shown in FIG. 2, in some embodiments, the word line exit regions 206 horizontally extend in the Y-direction, and are horizontally interposed, in the X-direction, between neighboring array regions 202. The word line exit regions 206 may, for example, horizontally alternate with the array regions 202 in the X-direction.

With continued reference to FIG. 2, the minigap regions 208 of the memory array structure 200 may comprise further horizontal areas of the memory array structure 200 including conductive contact structures and routing structures configured and positioned to facilitate electrical connections between one or more other features of the memory array structure 200 and/or the control circuitry structure 300 (FIG. 1). Some of the minigap regions 208 may individually be horizontally positioned between opposing corners of at least two (2) (e.g., two, four) of the array regions 202 horizontally neighboring one another. An individual minigap region 208 may be horizontally interposed, in the X-direction, between two (2) neighboring digit line exit regions 204; and may be substantially horizontally aligned, in the Y-direction, with each of the two (2) neighboring digit line exit regions 204. In addition, an individual minigap region 208 may be horizontally interposed, in the Y-direction, between two (2) neighboring word line exit regions 206; and may be substantially horizontally aligned, in the X-direction, with each of the two (2) neighboring word line exit regions 206. The minigap regions 208 of the memory array structure 200 may respectively be free of digit line structures and word line structures within a horizontal area thereof.

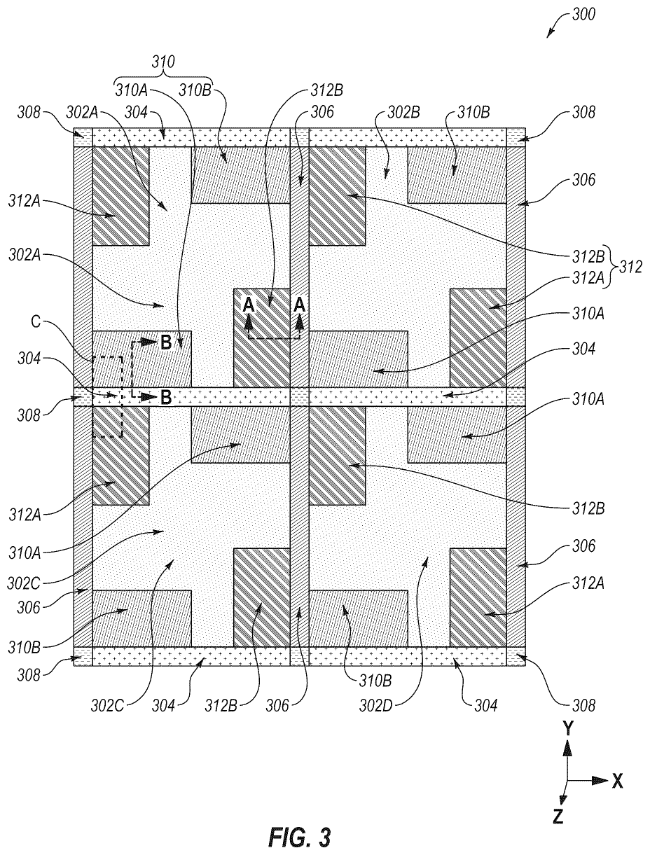

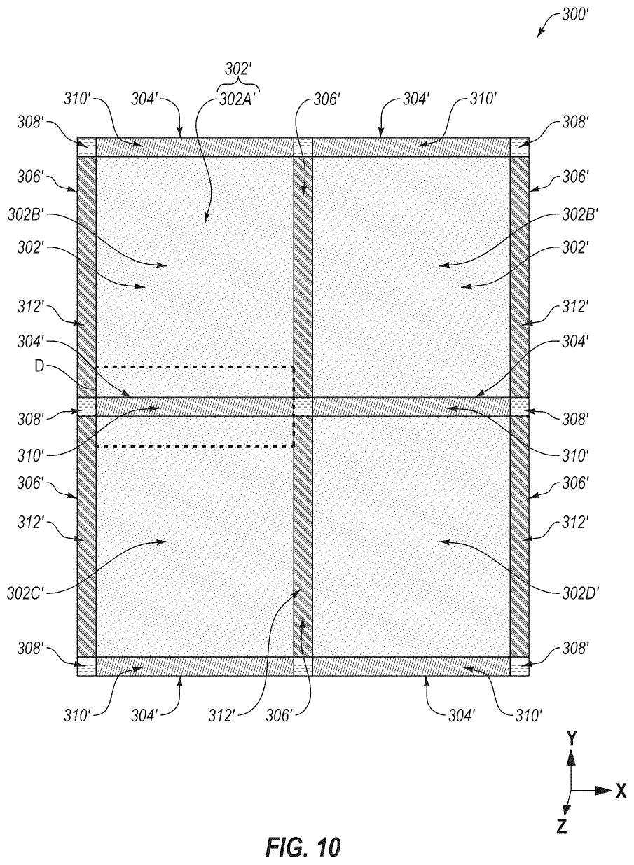

FIG. 3 is a simplified, partial schematic view of a portion of the control circuitry structure 300 of the microelectronic device 100 (FIG. 1), in accordance with some embodiments of the disclosure. FIG. 3 shows an arrangement of various circuitry of the control circuitry structure 300. The control circuitry structure 300 may have a so-called “quilt” arrangement of different control logic circuitry (e.g., SA circuitry, SWD circuitry) thereof, as described in further detail below. In additional embodiments, the control circuitry structure 300 has a different configuration than that described below with reference to FIG. 3. For example, the control circuitry structure 300 may have a so-called “non-quilt” arrangement of different control logic circuitry (e.g., SA circuitry, SWD circuitry) thereof, as described in further detail below with reference to FIG. 10.

As shown in FIG. 3, the control circuitry structure 300 may include control circuitry regions 302, digit line contact regions 304 interposed between pairs of the control circuitry regions 302 horizontally neighboring one another in the Y-direction, word line contact regions 306 interposed between additional pairs of the control circuitry regions 302 horizontally neighboring one another in the X-direction orthogonal to the Y-direction, and additional minigap regions 308 interposed between neighboring pairs of the digit line contact regions 304 in the X-direction and neighboring pairs of the word line contact regions 306 in the Y-direction. The control circuitry regions 302, the digit line contact regions 304, the word line contact regions 306, and the additional minigap regions 308 of the control circuitry structure 300 are each described in further detail below.

The control circuitry regions 302 of the control circuitry structure 300 respectively include control logic circuitry of the control circuitry structure 300 within a horizontal area thereof. The control logic circuitry of the control circuitry regions 302 of the control circuitry structure 300 may be operatively associated with circuitry (e.g., memory cells) of the memory array structure 200 (FIG. 2), as described in further detail below. In some embodiments, the control circuitry regions 302 are individually configured to at least partially (e.g., substantially) horizontally overlap a respective array region 202 (FIG. 2) of the memory array structure 200 (FIG. 2).

The control circuitry structure 300 may be formed to include a desired quantity of the control circuitry regions 302. For clarity and ease of understanding of the drawings and related description, FIG. 3 depicts the control circuitry structure 300 as including four (4) control circuitry regions 302: a first control circuitry region 302A, a second control circuitry region 302B, a third control circuitry region 302C, and a fourth control circuitry region 302D. As shown in FIG. 3, the second control circuitry region 302B may horizontally neighbor the first control circuitry region 302A in the X-direction, and may horizontally neighbor the fourth control circuitry region 302D in the Y-direction; the third control circuitry region 302C may horizontally neighbor the first control circuitry region 302A in the Y-direction, and may horizontally neighbor the fourth control circuitry region 302D in the X-direction; and the fourth control circuitry region 302D may horizontally neighbor the third control circuitry region 302C in the X-direction, and may horizontally neighbor the second control circuitry region 302B in the Y-direction. The first control circuitry region 302A may at least partially (e.g., substantially) horizontally overlap the first array region 202A (FIG. 2) of the memory array structure 200 (FIG. 2); the second control circuitry region 302B may at least partially (e.g., substantially) horizontally overlap the second array region 202B of the memory array structure 200 (FIG. 2); the third control circuitry region 302C may at least partially (e.g., substantially) horizontally overlap the third array region 202C (FIG. 2) of the memory array structure 200 (FIG. 2); and the fourth control circuitry region 302D may at least partially (e.g., substantially) horizontally overlap the fourth array region 202D (FIG. 2) of the memory array structure 200 (FIG. 2). However, the control circuitry structure 300 may include a different quantity of control circuitry regions 302. For example, the control circuitry structure 300 may be formed to include greater than four (4) control circuitry regions 302, such as greater than or equal to eight (8) control circuitry regions 302, greater than or equal to sixteen (16) control circuitry regions 302, greater than or equal to thirty-two (32) control circuitry regions 302, greater than or equal to sixty-four (64) control circuitry regions 302, greater than or equal to one hundred twenty-eight (128) control circuitry regions 302, greater than or equal to two hundred fifty-six (256) control circuitry regions 302, greater than or equal to five hundred twelve (512) control circuitry regions 302, or greater than or equal to one thousand twenty-four (1024) control circuitry regions 302. In some embodiments, a quantity of the control circuitry regions 302 of the control circuitry structure 300 substantially equals a quantity of the array regions 202 (FIG. 2) of the memory array structure 200 (FIG. 2).

Within a horizontal area of an individual control circuitry region 302, the control circuitry structure 300 may include, without limitation, SA sub-regions 310 and SWD sub-regions 312. An individual control circuitry region 302 may include two (2) SA sub-regions 310 (e.g., a first SA sub-region 310A and a second SA sub-region 310B), and two (2) SWD sub-regions 312 (e.g., a first SWD sub-region 312A and a second SWD sub-region 312B). The SA sub-regions 310 and SWD sub-regions 312 of respective control circuitry regions 302 of the control circuitry structure 300 are described in further detail below.

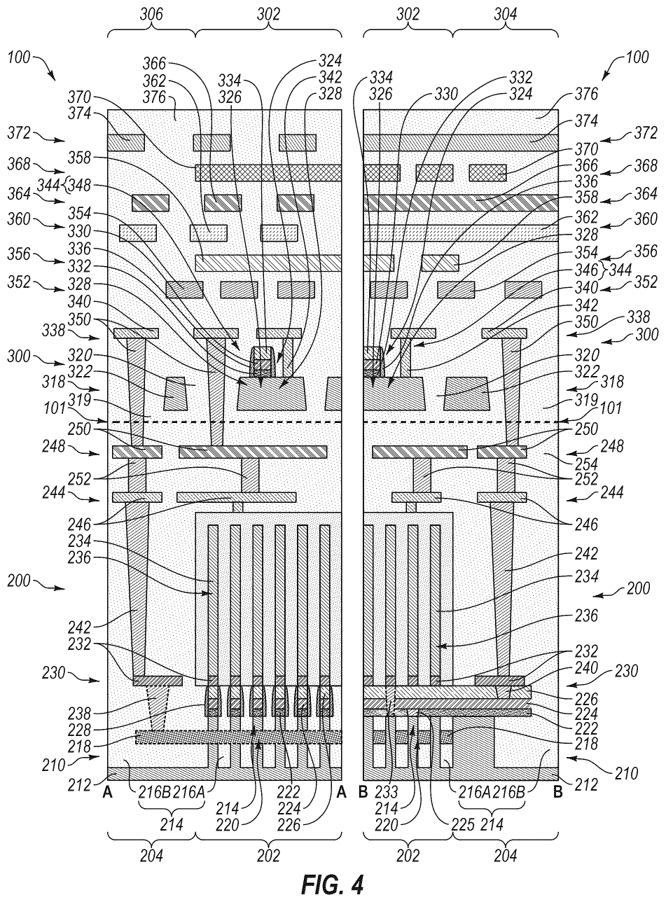

The SA sub-regions 310 of the control circuitry structure 300 may individually include SA devices and circuitry coupled to digit line structures within the memory array structure 200 (FIGS. 1 and 2). The SA sub-regions 310 may be substantially confined within horizontal areas of the control circuitry regions 302. An individual control circuitry region 302 may include one (1) first SA sub-region 310A and one (1) second SA sub-region 310B. An individual first SA sub-region 310A and an individual second SA sub-region 310B of the control circuitry structure 300 within a horizontal area an individual control circuitry region 302 may be positioned at or proximate opposite corners (e.g., diagonally opposite corners) of the control circuitry region 302 than one another. For example, as shown in FIG. 4, for an individual control circuitry region 302, the first SA sub-region 310A thereof may be horizontally positioned at or proximate a first corner of the control circuitry region 302, and the individual second SA sub-region 310B thereof may be horizontally positioned at or proximate a second corner of the control circuitry region 302 located diagonally opposite (e.g., kitty-corner) the first corner. In additional embodiments, for one or more of the control circuitry regions 302, the positions of the first SA sub-region 310A and the second SA sub-region 310B thereof are switched (e.g., swapped) relative to the arrangements depicted in FIG. 3.

As shown in FIG. 3, the SA sub-regions 310 (e.g., first SA sub-region 310A and the second SA sub-region 310B) may respectively exhibit a generally rectangular horizontal cross-sectional shape. First, relatively larger (e.g., major) sides of an individual SA sub-region 310 may horizontally extend in parallel, in the X-direction; and second, relatively smaller (e.g., minor) sides of an individual SA sub-region 310 may horizontally extend, in the Y-direction orthogonal to the X-direction. In some embodiments, for an individual SA sub-region 310, the first, relatively larger sides thereof extending in the X-direction are about two times (2×) larger than the second, relatively smaller sides thereof extending in the Y-direction.

SA devices of SA sub-regions 310 within control circuitry regions 302 horizontally neighboring one another in the Y-direction (e.g., the first control circuitry region 302A and the third control circuitry region 302C; the second control circuitry region 302B and the fourth control circuitry region 302D) may be coupled to different groups of digit line structures of the memory array structure 200 (FIG. 2) than one another. For example, each of the SA sub-regions 310 (e.g., each of the first SA sub-region 310A and the second SA sub-region 310B) of the control circuitry structure 300 within the first control circuitry region 302A may include so-called “even” SA devices coupled to even digit line structures within the memory array structure 200 (FIG. 2) by way of the digit line routing and contact structures associated with the SA sub-regions 310; and each of the SA sub-regions 310 (e.g., each of the first SA sub-region 310A and the second SA sub-region 310B) of the control circuitry structure 300 within the third control circuitry region 302C may include so-called “odd” SA devices coupled to odd digit line structures within the memory array structure 200 (FIG. 2) by way of the digit line routing and contact structures associated with the SA sub-regions 310; or vice versa. The even digit line structures of the memory array structure 200 (FIG. 2) may horizontally alternate with the odd digit line structures of the memory array structure 200 (FIG. 2) in the X-direction. The SA devices of each of the SA sub-regions 310 of the control circuitry structure 300 within horizontal area of the first control circuitry region 302A may not be coupled to any odd digit line structures of the memory array structure 200 (FIG. 2); and the SA devices of each of the SA sub-regions 310 of the control circuitry structure 300 within the horizontal area of the third control circuitry region 302C may not be coupled to any even digit line structures of the memory array structure 200 (FIG. 2); or vice versa. Similarly, each of the SA sub-regions 310 (e.g., each of the first SA sub-region 310A and the second SA sub-region 310B) of the control circuitry structure 300 within the second control circuitry region 302B horizontally neighboring the first control circuitry region 302A in the X-direction may include additional even SA devices coupled to additional even digit line structures within the memory array structure 200 (FIG. 2) by way of the digit line routing and contact structures associated with the SA sub-regions 310; and each of the SA sub-regions 310 (e.g., each of the first SA sub-region 310A and the second SA sub-region 310B) of the control circuitry structure 300 within the horizontal area of the fourth control circuitry region 302D horizontally neighboring the second control circuitry region 302B in the Y-direction may include additional odd SA devices coupled to additional odd digit line structures within the memory array structure 200 (FIG. 2) by way of the digit line routing and contact structures associated with the SA sub-regions 310; or vice versa.

The SWD sub-regions 312 of the control circuitry structure 300 may individually include SWD devices and circuitry coupled to word line structures within the memory array structure 200 (FIGS. 1 and 2). The SWD sub-regions 312 may be substantially confined within horizontal areas of the control circuitry regions 302. An individual control circuitry region 302 may include one (1) first SWD sub-region 312A and one (1) second SWD sub-region 312B. An individual first SWD sub-region 312A and an individual second SWD sub-region 312B of the control circuitry structure 300 within a horizontal area an individual control circuitry region 302 of the microelectronic device 100 may be positioned at or proximate different corners of the control circuitry region 302 than the first SA sub-region 310A and the second SA sub-region 310B of the control circuitry region 302. In addition, the corner of the control circuitry region 302 associated with the first SWD sub-region 312A may oppose (e.g., diagonally oppose) the corner of the control circuitry region 302 associated with second SWD sub-region 312B. For example, as shown in FIG. 3, for an individual control circuitry region 302, the first SWD sub-region 312A may be positioned at or proximate a third corner of the control circuitry region 302, and the second SWD sub-region 312B may be positioned at or proximate a fourth corner of the control circuitry region 302 located diagonally opposite (e.g., kitty-corner) the third corner. In additional embodiments, for one or more of the control circuitry regions 302, the positions of the first SWD sub-region 312A and the second SWD sub-region 312B thereof are switched (e.g., swapped) relative to the arrangements depicted in FIG. 3.

As shown in FIG. 3, the SWD sub-regions 312 (e.g., first SWD sub-region 312A and the second SWD sub-region 312B) may respectively exhibit a generally rectangular horizontal cross-sectional shape. First, relatively larger (e.g., major) sides of an individual SWD sub-region 312 may horizontally extend in parallel, in the Y-direction; and second, relatively smaller (e.g., minor) sides of an individual SWD sub-region 312 may horizontally extend, in the X-direction orthogonal to the Y-direction. In some embodiments, for an individual SWD sub-region 312, the first, relatively larger sides thereof extending in the Y-direction are about two times (2×) larger than the second, relatively smaller sides thereof extending in the X-direction.

For an individual control circuitry region 302 of the microelectronic device 100, the SWD devices of SWD sub-regions 312 within control circuitry regions 302 horizontally neighboring one another in the X-direction (e.g., the first control circuitry region 302A and the second control circuitry region 302B; the third control circuitry region 302C and the fourth control circuitry region 302D) may be coupled to different groups of word line structures than one another. For example, each of the SWD sub-regions 312 (e.g., each of the first SWD sub-region 312A and the second SWD sub-region 312B) of the control circuitry structure 300 within the first control circuitry region 302A may include so-called “even” SWD devices coupled to even word line structures within the memory array structure 200 (FIG. 2) by way of the word line routing and contact structures associated with the SWD sub-regions 312; and each of the SWD sub-regions 312 (e.g., each of the first SWD sub-region 312A and the second SWD sub-region 312B) of the control circuitry structure 300 within the second control circuitry region 302B may include so-called “odd” SWD devices coupled to odd word line structures within the memory array structure 200 (FIG. 2) by way of the word line routing and contact structures associated with the SWD sub-regions 312; or vice versa. The even word line structures of the memory array structure 200 (FIG. 2) may horizontally alternate with the odd word line structures of the memory array structure 200 (FIG. 2) in the Y-direction. The SWD devices of each of the SWD sub-regions 312 of the control circuitry structure 300 within horizontal area of the first control circuitry region 302A may not be coupled to any odd word line structures; and the SWD devices of each of the SWD sub-regions 312 of the control circuitry structure 300 within horizontal area of the second control circuitry region 302B may not be coupled to any even word line structures; or vice versa. Similarly, each of the SWD sub-regions 312 (e.g., each of the first SWD sub-region 312A and the second SWD sub-region 312B) of the control circuitry structure 300 within the third control circuitry region 302C horizontally neighboring the first control circuitry region 302A in the Y-direction may include additional even SWD devices coupled to additional even word line structures within the memory array structure 200 (FIG. 2) by way of the word line routing and contact structures associated with the SWD sub-regions 312; and each of the SWD sub-regions 312 (e.g., each of the first SWD sub-region 312A and the second SWD sub-region 312B) of the control circuitry structure 300 within the fourth control circuitry region 302D horizontally neighboring the third control circuitry region 302C in the X-direction may include additional odd SWD devices coupled to additional odd word line structures within the memory array structure 200 (FIG. 2) by way of the word line routing and contact structures associated with the SWD sub-regions 312; or vice versa.

Still referring to FIG. 3, the digit line contact regions 304 of the control circuitry structure 300 may comprise horizontal areas of the control circuitry structure 300 including additional routing structures and additional contact structures coupled to respective digit line structures of the memory array structure 200 (FIGS. 1 and 2) terminating within respective digit line exit regions 204 (FIG. 2) of the memory array structure 200 (FIGS. 1 and 2). As described in further detail below, the additional routing structures and the additional contact structures within the digit line contact regions 304 of the control circuitry structure 300 may be coupled to routing structures and contact structures within the digit line exit regions 204 (FIG. 2) of the memory array structure 200 (FIGS. 1 and 2). At least some of the additional routing structures and the additional contact structures within the digit line contact regions 304 may couple the digit line structures of the memory array structure 200 (FIGS. 1 and 2) to SA devices within the SA sub-regions 310 of the control circuitry structure 300. The digit line contact regions 304 of the control circuitry structure 300 are configured to at least partially (e.g., substantially) horizontally overlap respective digit line exit regions 204 (FIG. 2) of the memory array structure 200 (FIGS. 1 and 2). In some embodiments, a quantity of the digit line contact regions 304 of the control circuitry structure 300 substantially equals a quantity of the digit line exit regions 204 (FIG. 2) of the memory array structure 200 (FIGS. 1 and 2). As shown in FIG. 3, in some embodiments, the digit line contact regions 304 horizontally extend in the X-direction, and are respectively horizontally interposed, in the Y-direction, between neighboring control circuitry regions 302. The digit line contact regions 304 may, for example, horizontally alternate with the control circuitry regions 302 in the Y-direction.

The word line contact regions 306 of the control circuitry structure 300 may comprise additional horizontal areas of the control circuitry structure 300 including additional routing structures and additional contact structures coupled to respective word line structures of the memory array structure 200 (FIGS. 1 and 2) terminating within respective word line exit regions 206 (FIG. 2) of the memory array structure 200 (FIGS. 1 and 2). As described in further detail below, the additional routing structures and the additional contact structures within the word line contact regions 306 of the control circuitry structure 300 may be coupled to routing structures and contact structures within the word line exit regions 206 (FIG. 2) of the memory array structure 200 (FIGS. 1 and 2). At least some of the additional routing structures and the additional contact structures within the word line contact regions 306 may couple the word line structures of the memory array structure 200 (FIGS. 1 and 2) to SWD devices within the SWD sub-regions 312 of the control circuitry structure 300. The word line contact regions 306 of the control circuitry structure 300 are configured to at least partially (e.g., substantially) horizontally overlap respective word line exit regions 206 (FIG. 2) of the memory array structure 200 (FIGS. 1 and 2). In some embodiments, a quantity of the word line contact regions 306 of the control circuitry structure 300 substantially equals a quantity of the word line exit regions 206 (FIG. 2) of the memory array structure 200 (FIGS. 1 and 2). As shown in FIG. 3, in some embodiments, the word line contact regions 306 horizontally extend in the Y-direction, and are respectively horizontally interposed, in the X-direction, between neighboring control circuitry regions 302. The word line contact regions 306 may, for example, horizontally alternate with the control circuitry regions 302 in the X-direction.

The additional minigap regions 308 of the control circuitry structure 300 may comprise additional horizontal areas of the control circuitry structure 300 at least including further routing structures (e.g., control signal routing structures, column select routing structures, global input/output (GIO) routing structures, local input/output (LIO) routing structures, bussing routing structures) of the microelectronic device 100 (FIG. 1) within a horizontal area thereof. For an additional minigap regions 308, the further routing structures may individually horizontally extend (e.g., in the X-direction, in the Y-direction) through the additional minigap regions 308 en route to various circuitry and devices of the control circuitry structure 300. Different further routing structures within horizontal areas of the additional minigap regions 308 may be positioned at different vertical elevations (e.g., in the Z-direction) than one another. The additional minigap regions 308 of the control circuitry structure 300 are configured to at least partially (e.g., substantially) horizontally overlap respective minigap regions 208 (FIG. 2) of the memory array structure 200 (FIGS. 1 and 2). In some embodiments, a quantity of the additional minigap regions 308 of the control circuitry structure 300 substantially equals a quantity of the minigap regions 208 (FIG. 2) of the memory array structure 200 (FIGS. 1 and 2). As shown in FIG. 3, some of the additional minigap regions 308 may individually be horizontally positioned between opposing corners of at least two (2) (e.g., two, four) of the control circuitry regions 302 horizontally neighboring one another. An individual additional minigap region 308 may be horizontally interposed, in the X-direction, between two (2) neighboring digit line contact regions 304; and may be substantially horizontally aligned, in the Y-direction, with each of the two (2) neighboring digit line contact regions 304. In addition, an individual additional minigap region 308 may be horizontally interposed, in the Y-direction, between two (2) neighboring word line contact regions 306; and may be substantially horizontally aligned, in the X-direction, with each of the two (2) neighboring word line contact regions 306.

FIG. 4 is a diagram showing different vertical cross sectional views of the microelectronic device 100 collectively shown in FIGS. 1 through 3, taken about lines A-A and B-B depicted in FIGS. 2 and 3. The vertical cross section of the microelectronic device 100 about line A-A is a view of an XZ-plane of a portion of the microelectronic device 100 horizontally overlapping one of the array regions 202 and one of the word line exit regions 206 of the memory array structure 200, and one of the control circuitry regions 302 and one of the word line contact regions 306 of the control circuitry structure 300. The vertical cross section of the microelectronic device 100 about line B-B is a view of an YZ-plane of a portion of the microelectronic device 100 horizontally overlapping the one of the array regions 202 and one of the digit line exit regions 204 of the memory array structure 200, and the one of the control circuitry regions 302 and one of the digit line contact regions 304 of the control circuitry structure 300. Within the microelectronic device 100, the control circuitry regions 302 of the control circuitry structure 300 vertically overlie and horizontally overlap the array regions 202 of the memory array structure 200; the digit line contact regions 304 of the control circuitry structure 300 vertically overlie and horizontally overlap the digit line exit regions 204 of the memory array structure 200; and the word line contact regions 306 of the control circuitry structure 300 vertically overlie and horizontally overlap the word line exit regions 206 of the memory array structure 200.

As shown in FIG. 4, the memory array structure 200 of the microelectronic device 100 may include a base structure 210 including semiconductor material 212 and isolation structures 216 (e.g., shallow trench isolation (STI) structures) vertically extending into the semiconductor material 212. The isolation structures 216 may define boundaries of active regions 214 of the semiconductor material 212, as described in further detail below.

The base structure 210 comprises a base material or construction upon which additional features (e.g., materials, structures, devices) of the memory array structure 200 are formed. The base structure 210 may comprise a semiconductor structure (e.g., a semiconductor wafer), or a base semiconductor material on a supporting structure. For example, the base structure 210 may comprise a conventional silicon substrate (e.g., a conventional silicon wafer), or another bulk substrate comprising a semiconductor material. In some embodiments, the base structure 210 comprises a silicon wafer. The base structure 210 may include one or more layers, structures, and/or regions formed therein and/or thereon.

The isolation structures 216 of the memory array structure 200 may include trenches (e.g., openings, vias, apertures) within the semiconductor material 212 of base structure 210 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the isolation structures 216 are respectively formed of and include SiOₓ (e.g., SiO₂).

The isolation structures 216 may include first isolation structures 216A and second isolation structures 216B. The first isolation structures 216A may have one or more different geometric configuration(s) (e.g., different dimension(s), different shape(s)) and different horizontal positioning relative to the second isolation structures 216B. As shown in FIG. 4, in some embodiments, the first isolation structures 216A are respectively positioned within a horizontal area of a respective array region 202 of the memory array structure 200; and the second isolation structures 216B are respectively positioned within a horizontal area of a respective digit line exit regions 204 or a respective word line exit region 206 of the memory array structure 200. In addition, at least some of the first isolation structures 216A may respectively have different horizontal dimension(s) than at least some of the second isolation structures 216B. At least some of the isolation structures 216 (e.g., at least some of the first isolation structures 216A and/or at least some of the second isolation structures 216B) vertically extend to and terminate at a different vertical position than some other of the isolation structures 216 (e.g., at least some other of the first isolation structures 216A and/or at least some other of the second isolation structures 216B). For example, some of the isolation structures 216 may be formed to be relatively vertically shallower than some other of the isolation structures 216. Some of the isolation structures 216 may be employed as shallow trench isolation (STI) structures within the base structure 210.

Within an individual array region 202 of the memory array structure 200, some of the isolation structures 216 (e.g., some of the first isolation structures 216A) may at least partially define boundaries of the active regions 214 of the semiconductor material 212 of the base structure 210. The active regions 214 of the semiconductor material 212 may individually vertically extend (e.g., project) from a relatively lower portion of the semiconductor material 212 that horizontally extends across and between the active regions 214. The active regions 214 may be considered pillar structures of the semiconductor material 212.

The active regions 214 of the semiconductor material 212 may individually exhibit an elongate (e.g., non-circular, non-square) horizontal cross-sectional shape at least partially defined by the horizontal cross-sectional shapes of the first isolation structures 216A horizontally adjacent thereto. The active regions 214 may individually include an upper surface, opposing horizontal ends, and opposing horizontal sides extending from and between the opposing ends. Intersections of the opposing horizontal ends of an individual active region 214 with the opposing horizontal sides of the active region 214 may define horizontal corners of the active region 214. As shown in FIG. 4, the upper surfaces of the active regions 214 may be substantially coplanar with one another. In addition, an individual active region 214 may include a digit line contact region (e.g., bit line contact region) and storage node contact regions (e.g., cell contact regions). The storage node contact regions of the active region 214 may be located proximate the opposing horizontal ends of the active region 214, and the digit line contact region may be horizontally interposed between the storage node contact regions. The digit line contact region may be positioned at or proximate to a horizontal center of the active region 214. In some embodiments, the digit line contact region of an individual active region 214 is horizontally narrower (e.g., in the X-direction shown in FIGS. 1 through 3) than each of the storage node contact regions of the active region 214. The digit line contact region and the storage node contact regions of an individual active region 214 may be separated from one another by a pair of the first isolation structures 216A.

With continued reference to FIG. 4, word line structures 218 may be at least partially embedded within the isolation structures 216 and may horizontally extend in parallel in the X-direction (FIG. 1A) completely through the array region 202 and at least partially through the word line exit region 206. At least some of the word line structures 218 may terminate within the word line exit region 206. In FIG. 4, the illustrated word line structure 218 is depicted by way of dashed lines to represent that it is outside of (e.g., horizontally offset in the Y-direction (FIGS. 1 through 3) from) the vertical plane (e.g., XZ-plane) of line A-A. Tops (e.g., upper vertical boundaries) of the word line structures 218 may be substantially coplanar with one another. Side surfaces and a bottom surface of an individual word line structure 218 may be covered by insulative material of a respective one of the isolation structures 216. For example, portions of the isolation structure 216 may be horizontally interposed between the word line structure 218 and a respective active region 214 of the semiconductor material 212 of the base structure 210. The word line structures 218 may individually be formed of and include conductive material. In some embodiments, the word line structures 218 are individually formed of and include one or more of W, Ru, Mo, and TiN_{y}.

Within the array region 202, the memory array structure 200 further includes access devices 220. The access devices 220 may individually include a channel region comprising a portion of an active region 214 of the semiconductor material 212 of the base structure 210; a source region and a drain region respectively horizontally neighboring the channel region and individually comprising a conductively doped portion of the active region 214 of the semiconductor material 212 of the base structure 210; at least one gate comprising a portion of at least one of the word line structures 218; and a gate dielectric structure comprising a portion of the insulative material of the first isolation structure 216A interposed between the channel region thereof and the gate thereof.

The memory array structure 200 may further include a first dielectric material 222 on or over the base structure 210. Within the array region 202, the first dielectric material 222 may overlie the access devices 220. The first dielectric material 222 may be formed of and include insulative material. In some embodiments, the first dielectric material 222 is formed of and includes dielectric oxide material (e.g., SiOₓ, such as SiO₂).

With continued reference to FIG. 4, digit line structures 224 may vertically overlie the first dielectric material 222 and may individually horizontally extend in parallel in the Y-direction (FIGS. 1 through 3) completely through a respective array region 202 and at least partially through a respective digit line exit region 204. At least some of the digit line structures 224 may terminate within the digit line exit region 204. As shown in FIG. 4, tops (e.g., upper vertically boundaries) of the digit line structures 224 may be substantially coplanar with one another. The digit line structures 224 may individually be formed of and include conductive material. In some embodiments, the digit line structures 224 are individually formed of and include one or more of W, Ru, Mo, and TiN_{y}.

Still referring to FIG. 4, digit line capping structures 226 may be formed on or over upper surfaces of the digit line structures 224, and digit line spacer structures 228 may be formed on or over side surfaces (e.g., sidewalls) of the digit line structures 224. The digit line capping structures 226 may at least partially (e.g., substantially) cover the upper surfaces of the digit line structures 224, and the digit line spacer structures 228 may at least partially (e.g., substantially) cover the side surfaces of the digit line structures 224. As shown in FIG. 4, in some embodiments, upper boundaries of the digit line spacer structures 228 vertically overlie the upper surfaces of the digit line structures 224, and lower boundaries of the digit line spacer structures 228 vertically underlie lower surfaces of the digit line structures 224. The digit line capping structures 226 and the digit line spacer structures 228 may individually be formed of and include at least one insulative material. In some embodiments, the digit line capping structures 226 and the digit line spacer structures 228 are individually formed of and include one or more of dielectric oxide material (e.g., SiOₓ, such as SiO₂) and dielectric nitride material (e.g., SiN_{y}, such as Si₃N₄).

Within the array region 202, the memory array structure 200 may further include first digit line contact structures 225 (also referred to herein as “DIGITCON” structures) vertically overlying and in contact with the active regions 214 of the semiconductor material 212 of the base structure 210. The first digit line contact structures 225 may vertically extend through the first dielectric material 222 and into the active regions 214 of the semiconductor material 212 of the base structure 210. The first digit line contact structures 225 horizontally overlap (e.g., in the X-direction and the Y-direction shown in FIGS. 1 through 3) digit line contact sections of the active regions 214. The first digit line contact structures 225 may respectively vertically extend from a digit line contact section of an individual active region 214, through the first dielectric material 222, and to an individual digit line structure 224. An individual first digit line contact structure 225 may be horizontally interposed between two (2) of the word line structures 218 (and, hence, two (2) of the isolation structures 216) neighboring one another in the Y-direction (FIGS. 1 through 3), and may be horizontally interposed between two (2) of storage node contact sections of an individual active region 214 in an additional horizontal direction angled relative to the Y-direction (FIGS. 1 through 3) and the X-direction (FIGS. 1 through 3). An individual first digit line contact structure 225 may be coupled to one of the source/drain regions (e.g., the source region) of an individual access device 220 of the memory array structure 200. Within the horizontal area of an individual active region 214, an individual first digit line contact structure 225 may be coupled to two (2) (e.g., a pair) of the access devices 220 operatively associated with the active region 214. For example, the two (2) of the access devices 220 may share a source region within the active region 214 with one another, and the first digit line contact structure 225 may be coupled to the shared source region of the two (2) of the access devices 220. The first digit line contact structures 225 may individually be formed of and include conductive material.

Within the array region 202, the memory array structure 200 may further include storage node contact structures 233 (also referred to herein as “CELLCON” structures) vertically overlying and in contact with the active regions 214 of the semiconductor material 212 of the base structure 210. The storage node contact structures 233 may vertically extend through the first dielectric material 222 and into the active regions 214 of the semiconductor material 212 of the base structure 210. The storage node contact structures 233 horizontally overlap (e.g., in the X-direction and the Y-direction shown in FIGS. 1 through 3) storage node contact sections of the active regions 214. In FIG. 4, the illustrated storage node contact structure 233 is depicted by way of dashed lines to represent that it is outside of (e.g., horizontally offset in the X-direction (FIGS. 1 through 3) from) the vertical plane (e.g., YZ-plane) of line B-B. The storage node contact structures 233 may respectively vertically extend from a storage node contact section of an individual active region 214, through the first dielectric material 222, and to first routing structure 232 vertically overlying the digit line capping structures 226. An individual storage node contact structure 233 may be horizontally interposed between two (2) of the word line structures 218 (and, hence, two (2) of the isolation structures 216) neighboring one another in the Y-direction (FIGS. 1 through 3), and may horizontally neighbor the digit line contact section of an individual active region 214 in an additional horizontal direction angled relative to the Y-direction (FIGS. 1 through 3) and the X-direction (FIGS. 1 through 3). An individual storage node contact structure 233 may be coupled to one of the source/drain regions (e.g., the drain region) of an individual access device 220 of the memory array structure 200. Within the horizontal area of an individual active region 214, an individual storage node contact structure 233 may be coupled to one (1) of two (2) (e.g., a pair) of access devices 220 operatively associated with the active region 214. For example, the two (2) of the access devices 220 have separate drain regions than one another within the active region 214, and the individual storage node contact structure 233 may be coupled to the drain region of one (1) of the two (2) of the access devices 220. An individual active region 214 of the semiconductor material 212 may have two (2) storage node contact structures 233 in contact therewith. The storage node contact structures 233 may individually be formed of and include conductive material.

Still referring to FIG. 4, a first routing tier 230 may be formed to vertically overlie the digit line capping structures 226 and may include first routing structures 232. Within the array region 202, at least some of the first routing structures 232 may, for example, be employed to facilitate a horizontal arrangement (e.g., a hexagonal close packed arrangement) of storage node devices 234 that is different than a horizontal arrangement of the storage node contact structures 233, while electrically connecting the storage node contact structures 233 (and, hence, the access devices 220) to the storage node devices 234. In addition, within the digit line exit regions 204 and the word line exit regions 206, at least some other of the first routing structures 232 may vertically extend between and couple vertically neighboring conductive contact structures within the digit line exit regions 204 and the word line exit regions 206, as described in further detail below. The first routing structures 232 may individually be formed of and include conductive material. In some embodiments, the first routing structures 232 are individually formed of and include one or more of W, Ru, Mo, and TiN_{y}.

Within the array region 202, the storage node devices 234 (e.g., capacitors) may be formed on or over the first routing structures 232. The storage node devices 234 may be in electrical contact with the first routing structures 232, and, hence with the storage node contact structures 233 and the access devices 220. The storage node devices 234 may be coupled to the access devices 220 by way of the storage node contact structures 233 and the first routing structures 232 to form memory cells 236 (e.g., volatile memory cells, such as DRAM cells) within the array region 202. Each memory cell 236 may individually include one of the access devices 220, one of the storage node devices 234, one of the storage node contact structures 233, and one of the first routing structures 232. The storage node devices 234 may individually be formed and configured to store a charge representative of a programmable logic state of the memory cell 236 including the storage node device 234. In some embodiments, the storage node devices 234 are capacitors. During use and operation, a charged capacitor may represent a first logic state, such as a logic 1; and an uncharged capacitor may represent a second logic state, such as a logic 0. Each of the storage node devices 234 may, for example, be formed to include a first electrode (e.g., a bottom electrode), a second electrode (e.g., a top electrode), and a dielectric material between the first electrode and the second electrode.

Still referring to FIG. 4, the memory array structure 200 may further include a second routing tier 244 vertically overlying the memory cells 236 and including second routing structures 246. The second routing structures 246 may, for example, include one or more of pad structures and line structures. The second routing structures 246 may respectively be formed of and include conductive material. In some embodiments, the second routing structures 246 are individually formed of and include one or more of W, Ru, Mo, and TiN_{y}.

Within the word line exit regions 206, the memory array structure 200 further includes word line contact structures 238. Within an individual word line exit region 206, the word line contact structures 238 may vertically extend between and couple some of the first routing structures 232 and some of the word line structures 218. The word line contact structures 238 may be considered to be so-called “edge of array” word line contact structures. In the FIG. 4, the illustrated word line contact structures 238 is depicted by way of dashed lines to represent that it is outside of (e.g., horizontally offset in the Y-direction (FIGS. 1 through 3) from) the vertical plane (e.g., XZ-plane) of line A-A. An individual word line contact structure 238 may be formed to have an upper surface in physical contact with one of the first routing structures 232; and a lower surface on, within, or below one of the word line structures 218. The word line contact structures 238 may respectively be formed of and include conductive material. In some embodiments, the word line contact structures 238 are individually formed of and include one or more of W, Ru, Mo, and TiN_{y}.

Within the digit line exit regions 204, the memory array structure 200 further includes second digit line contact structures 240. Within an individual digit line exit region 204, the second digit line contact structures 240 may vertically extend between and couple some of the first routing structures 232 and some of the digit line structures 224. The second digit line contact structures 240 may be considered to be so-called “edge of array” digit line contact structures. An individual second digit line contact structure 240 may be formed to have an upper surface in physical contact with one of the first routing structures 232; and a lower surface on, within, or below one of the digit line structures 224. The second digit line contact structures 240 may respectively be formed of and include conductive material. In some embodiments, the second digit line contact structures 240 are individually formed of and include one or more of W, Ru, Mo, and TiN_{y}.

Within the word line exit regions 206 and the digit line exit regions 204, the memory array structure 200 further includes first contact structures 242 (e.g., deep contact structures). The first contact structures 242 vertically extend between and couple some of the first routing structures 232 of the first routing tier 230 and some of the second routing structures 246 of the second routing tier 244. An individual first contact structure 242 may have an upper surface in physical contact with one of the second routing structures 246; and a lower surface on, within, or below one of the first routing structures 232. The first contact structures 242 may be considered to be so-called “edge of array” contact structures. The first contact structures 242 may respectively be formed of and include conductive material. In some embodiments, the first contact structures 242 are individually formed of and include one or more of W, Ru, Mo, and TiN_{y}.

Still referring to FIG. 4, optionally, the memory array structure 200 may further include a third routing tier 248 vertically overlying the second routing tier 244 and including third routing structures 250. The third routing structures 250 may, for example, include one or more of pad structures and line structures. If the third routing tier 248 is included, the memory array structure 200 may also include second contact structures 252. The second contact structures 252 vertically extend between and couple some of the second routing structures 246 of the second routing tier 244 and some of the third routing structures 250 of the third routing tier 248. An individual second contact structure 252 may have an upper surface in physical contact with one of the third routing structures 250; and a lower surface on, within, or below one of the second routing structures 246. If included, the third routing structures 250 and the second contact structures 252 may respectively be formed of and include conductive material. In some embodiments, the third routing structures 250 and the second contact structures 252 are individually formed of and include one or more of W, Ru, Mo, and TiN_{y}. In additional embodiments, the third routing tier 248 (and, hence, the third routing structures 250 thereof) and the second contact structures 252 are omitted (e.g., absent) from the microelectronic device 100, as described in further detail below.

Isolation material 254 may be formed on or over portions of at least the base structure 210, the first dielectric material 222, the digit line capping structures 226, the first routing structures 232, the storage node devices 234, the memory cells 236, the first contact structures 242, the second routing structures 246, the second contact structures 252 (if any), and the third routing structures 250 (if any). The isolation material 254 may be formed of and include insulative material. In some embodiments, the isolation material 254 is formed of and includes dielectric oxide material, such as SiOₓ (e.g., SiO₂). The isolation material 254 may be substantially homogeneous, or the isolation material 254 may be heterogeneous. In some embodiments, a portion of the isolation material 254 vertically overlies upper surfaces of the uppermost ones of the third routing structures 250.

Still referring next to FIG. 4, the control circuitry structure 300 of the microelectronic device 100 may be formed to include an additional base structure 318 including additional isolation material 319, additional semiconductor material 320 on or over the additional isolation material 319, and additional isolation structures 322 vertically extending through the additional semiconductor material 320 to the additional isolation material 319. The additional isolation material 319 may be bonded (e.g., dielectric-to-dielectric bonded, such as oxide-to-oxide bonded) to the isolation material 254 of the memory array structure 200 of the microelectronic device 100.

The additional base structure 318 comprises a base material or construction upon which additional features (e.g., materials, structures, devices) of the control circuitry structure 300 are formed. The additional base structure 318 may comprise a semiconductor structure (e.g., a semiconductor wafer), or a base semiconductor material on a supporting structure. For example, the additional base structure 318 may comprise a conventional silicon substrate (e.g., a conventional silicon wafer), or another bulk substrate comprising a semiconductor material. In some embodiments, the additional base structure 318 comprises a silicon wafer. The additional base structure 318 may include one or more layers, structures, and/or regions formed therein and/or thereon.

The additional isolation material 319 is formed of and includes insulative material. For example, the additional isolation material 319 may be formed of and includes dielectric oxide material, such as SiOₓ (e.g., SiO₂). The additional isolation material 319 may be substantially homogeneous, or the additional isolation material 319 may be heterogeneous.

The additional isolation structures 322 may comprise trenches (e.g., openings, vias, apertures) within the additional semiconductor material 320 of the additional base structure 318 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the additional isolation structures 322 are respectively formed of and include SiOₓ (e.g., SiO₂).

Still referring to FIG. 4, the control circuitry structure 300 may further include transistors 324. The transistors 324 may individually include conductively doped regions 328 (e.g., source/drain regions), a channel region 326, a gate structure 330 (e.g., a gate electrode), and a gate dielectric material 332. For an individual transistor 324, the conductively doped regions 328 thereof may be formed within the additional semiconductor material 320 of the additional base structure 318; the channel region 326 thereof may be formed within the additional semiconductor material 320 of the additional base structure 318 and may be horizontally interposed between the conductively doped regions 328 thereof; the gate structure 330 thereof may vertically overlie and horizontally overlap the channel region 326 thereof; and the gate dielectric material 332 (e.g., dielectric oxide material) may be vertically interposed (e.g., in the Z-direction (FIGS. 1 through 3)) between the gate structure 330 and the channel region 326.

For an individual transistor 324, the conductively doped regions 328 thereof may comprise additional semiconductor material 320 of the additional base structure 318 doped with one or more desired conductivity-enhancing dopants. In some embodiments, the conductively doped regions 328 of the transistor 324 comprise the additional semiconductor material 320 doped with at least one N-type dopant (e.g., one or more of phosphorus, arsenic, antimony, and bismuth). In some of such embodiments, the channel region 326 of the transistor 324 comprises the additional semiconductor material 320 doped with at least one P-type dopant (e.g., one or more of boron, aluminum, and gallium). In some other of such embodiments, the channel region 326 of the transistor 324 comprises substantially undoped additional semiconductor material 320. In additional embodiments, for an individual transistor 324, the conductively doped regions 328 thereof comprise the additional semiconductor material 320 doped with at least one P-type dopant (e.g., one or more of boron, aluminum, and gallium). In some of such additional embodiments, the channel region 326 of the transistor 324 comprises the additional semiconductor material 320 doped with at least one N-type dopant (e.g., one or more of phosphorus, arsenic, antimony, and bismuth). In some other of such additional embodiments, the channel region 326 of the transistor 324 comprises substantially undoped additional semiconductor material 320.

The gate structures 330 (e.g., gate electrodes, gates) may individually horizontally extend between and be employed by multiple transistors 324. The gate structures 330 may be formed of and include conductive material. The gate structures 330 may individually be substantially homogeneous, or the gate structures 330 may individually be heterogeneous. In some embodiments, the gate structures 330 are each substantially homogeneous. In additional embodiments, the gate structures 330 are each heterogeneous. Individual gate structures 330 may, for example, be formed of and include a stack of at least two different conductive materials.

Still referring to FIG. 4, gate capping structures 334 may be formed on or over upper surfaces of the gate structures 330; and gate spacer structures 336 may be formed on or over side surfaces (e.g., sidewalls) of the gate structures 330, the gate dielectric material 332, and the gate capping structures 334. The gate capping structures 334 and the gate spacer structures 336 may individually be formed of and include at least one insulative material. In some embodiments, the gate capping structures 334 and the gate spacer structures 336 are individually formed of and include one or more of dielectric oxide material (e.g., SiOₓ, such as SiO₂) and dielectric nitride material (e.g., SiN_{y}, such as Si₃N₄).

Still referring to FIG. 4, the control circuitry structure 300 further includes third contact structures 342 vertically overlying and in contact (e.g., physical contact, electrical contact) with the conductively doped regions 328 of the transistors 324. In some embodiments, the third contact structures 342 vertically overlie, horizontally overlap, and physically contact the conductively doped regions 328 of the transistors 324. The third contact structures 342 may individually be formed of and include conductive material. In some embodiments, the third contact structures 342 are individually formed of and include one or more of W, Ru, Mo, and TiN_{y}.

The control circuitry structure 300 further includes a fourth routing tier 338 vertically over the transistors 324 and including fourth routing structures 340. The fourth routing structures 340 may, for example, include one or more of pad structures and line structures. As shown in FIG. 4, some of the fourth routing structures 340 may be coupled to the third contact structures 342 (and, hence, the transistors 324). The fourth routing structures 340 may respectively be formed of and include conductive material. In some embodiments, the fourth routing structures 340 are individually formed of and include one or more of W, Ru, Mo, and TiN_{y}.

With continued reference to FIG. 4, the transistors 324, the third contact structures 342, and at least some of the fourth routing structures 340 may form control logic circuitry of various control logic devices 344 configured to control various operations of various features (e.g., the memory cells 236) of the microelectronic device 100. In some embodiments, the control logic devices 344 comprise complementary metal-oxide-semiconductor (CMOS) circuitry. As a non-limiting example, the control logic devices 344 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), Vad regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry.

Different regions of the control circuitry structure 300 may include different control logic devices 344 formed within horizontal areas thereof. For example, referring collectively to FIGS. 3 and 4, within a horizontal area of an individual SA sub-region 310 (e.g., a first SA sub-region 310A, a second SA sub-region 310B) (FIG. 3) within a respective control circuitry region 302 (e.g., the first control circuitry region 302A (FIG. 3)) of the control circuitry structure 300, the control logic devices 344 may include SA devices 346. As another example, still referring collectively to FIGS. 3 and 4, within a horizontal area of an individual SWD sub-region 312 (e.g., a first SWD sub-region 312A, a second SWD sub-region 312B) (FIG. 3) within a respective control circuitry region 302 (e.g., the first control circuitry region 302A (FIG. 3)), the control logic devices 344 may include SWD devices 348.

Referring to FIG. 4, a front side of the control circuitry structure 300 may be considered to be a side (e.g., end surface) most proximate to the control logic devices 344 (e.g., most proximate to the fourth routing structures 340 of the fourth routing tier 338), and a back side of the control circuitry structure 300 may be considered to be an additional side (e.g., additional end surface) relatively more distal from the control logic devices 344 (e.g., most proximate to the additional isolation material 319) than the front side. In addition, a front side of the memory array structure 200 may be considered to be a side (e.g., end surface) most proximate to the third routing structures 250 of the third routing tier 248, and a back side of the additional memory array structure 200 may be considered to be an additional side (e.g., additional end surface) most proximate to the base structure 210. Accordingly, in the configuration shown in FIG. 4, the microelectronic device 100 may be formed to have a so-called “back-to-front” (B2F) arrangement of the control circuitry structure 300 relative to the memory array structure 200.

Still referring to FIG. 4, fourth contact structures 350 may be formed to vertically extend from some of the fourth routing structures 340 of the fourth routing tier 338 vertically overlying the control logic devices 344 to some of the third routing structures 250 of the third routing tier 248 (if any) vertically underlying the control logic devices 344. An individual fourth contact structure 350 may couple at least one of the fourth routing structures 340 to at least one of the third routing structures 250. In additional, embodiments, such as embodiments wherein the third routing tier 248 including the third routing structures 250 is not present in the microelectronic device 100, the fourth contact structures 350 may be formed to vertically extend from some of the fourth routing structures 340 of the fourth routing tier 338 to some of the second routing structures 246 of the second routing tier 244. One or more (e.g., each) of the fourth contact structures 350 may be formed to horizontally overlap and vertically extend through one or more of the additional isolation structures 322 of the control circuitry structure 300. Optionally, one or more other of the fourth contact structures 350 may be formed to horizontally overlap and vertically extend through the additional semiconductor material 320 of the control circuitry structure 300. The fourth contact structures 350 may be formed after bonding the control circuitry structure 300 to the memory array structure 200. The fourth contact structures 350 may respectively be formed of and include conductive material. In some embodiments, the fourth contact structures 350 are individually formed of and include one or more of W, Ru, Mo, and TiN_{y}.

The fourth contact structures 350 may facilitate operable communication between the control logic devices 344 of the control circuitry structure 300 and the memory cells 236 of the memory array structure 200 vertically thereunder. For example, the fourth contact structures 350, in combination at least with the fourth routing structures 340 of the fourth routing tier 338, the third routing structures 250 of the third routing tier 248 (if any), the second contact structures 252 (if any), the second routing structures 246 of the second routing tier 244, the first contact structures 242, the first routing structures 232 of the first routing tier 230, the second digit line contact structures 240, the digit line structures 224, the first digit line contact structures 225, the word line contact structure 238, and the word line structures 218, may facilitate conductive paths between the different control logic devices 344 of the control circuitry structure 300 and the memory cells 236 of the memory array structure 200.

Still referring to FIG. 4, the microelectronic device 100 further includes additional routing tiers (e.g., local routing tiers; global routing tiers) respectively including additional routing structures (e.g., local routing structures, global routing structures) vertically overlying the fourth routing tier 338. As a non-limiting example, the microelectronic device 100 may include a fifth routing tier 352 including fifth routing structures 354, a sixth routing tier 356 including sixth routing structures 358, a seventh routing tier 360 including seventh routing structures 362, an eighth routing tier 364 including eighth routing structures 366, a ninth routing tier 368 including ninth routing structures 370, and a tenth routing tier 372 including tenth routing structures 374. The fifth routing tier 352 may vertically overlie the fourth routing tier 338, the sixth routing tier 356 may vertically overlie the fifth routing tier 352, the seventh routing tier 360 may vertically overlie the sixth routing tier 356, the eighth routing tier 364 may vertically overlie the seventh routing tier 360, the ninth routing tier 368 may vertically overlie the eighth routing tier 364, and the tenth routing tier 372 may vertically overlie the ninth routing tier 368. The different additional routing tiers may be employed for different functions (e.g., different signal routing functions) of the microelectronic device 100, as described in further detail below.

Within the fifth routing tier 352, the fifth routing structures 354 thereof may be employed for various operational functions of the microelectronic device 100. Operational functions facilitated by the fifth routing structures 354 of the fifth routing tier 352 may be at least partially different than the operational functions facilitated by the fourth routing structures 340 of the fourth routing tier 338. In some embodiments, the fifth routing tier 352 is at least partially (e.g., substantially) employed as a local routing tier, and at least some of the fifth routing structures 354 thereof are employed as local routing structures (also referred to herein as “local interconnect structures”). By way of non-limiting example, at least some of the fifth routing structures 354 of the fifth routing tier 352 may be employed as local routing structures to couple at least some of the control logic devices 344 of the control circuitry structure 300 to one another and/or other features (e.g., structures, devices) of the control circuitry structure 300. At some of the fifth routing structures 354 of the fifth routing tier 352 may be coupled to at least some of the fourth routing structures 340 of the fourth routing tier 338 by way of additional conductive contact structures vertically extending therebetween. The fifth routing structures 354 of the fifth routing tier 352 may individually be formed of and include conductive material. In some embodiments, the fifth routing structures 354 of the fifth routing tier 352 are individually formed of and include one or more of W, Ru, Mo, and TiN.

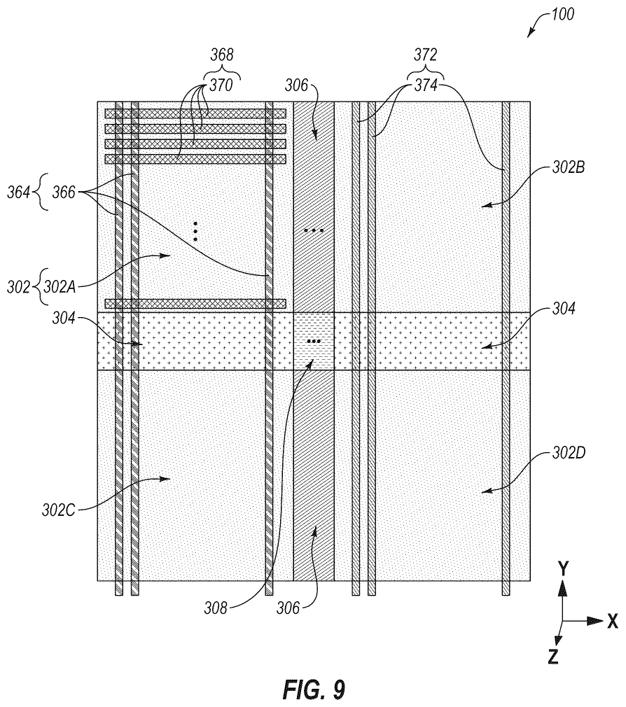

Within the sixth routing tier 356, the sixth routing structures 358 thereof may be employed for various additional operational functions of the microelectronic device 100. Operational functions facilitated by the sixth routing structures 358 of the sixth routing tier 356 may be at least partially different than the operational functions facilitated by the fourth routing structures 340 of the fourth routing tier 338 and the fifth routing structures 354 of the fifth routing tier 352. The operational function facilitated by an individual sixth routing structure 358 may at least partially depend on the horizontal location of the sixth routing structure 358, as described in further detail below with reference to FIG. 9. In some embodiments, the sixth routing tier 356 is at least partially (e.g., substantially) employed as a global routing tier (e.g., a first global routing tier), and at least some of the sixth routing structures 358 thereof are employed as global routing structures (e.g., first global routing structures). By way of non-limiting example, different sixth routing structures 358 of the sixth routing tier 356 may be employed as SA control signal routing structures, SWD control signal routing structures, main word line (MWL) control signal routing structures, and/or local input/output routing structures. The sixth routing structures 358 of the sixth routing tier 356 may individually be formed of and include conductive material. In some embodiments, the sixth routing structures 358 of the sixth routing tier 356 are individually formed of and include one or more of W, Cu, Ru, Mo, and TiN.

Within the seventh routing tier 360, the seventh routing structures 362 thereof may be employed for various further operational functions of the microelectronic device 100. Operational functions facilitated by the seventh routing structures 362 of the seventh routing tier 360 may be at least partially different than the operational functions facilitated by the fourth routing structures 340 of the fourth routing tier 338, the fifth routing structures 354 of the fifth routing tier 352, and the sixth routing structures 358 of the sixth routing tier 356. The operational function facilitated by an individual seventh routing structure 362 may at least partially depend on the horizontal location of the seventh routing structure 362, as described in further detail below with reference to FIG. 9. In some embodiments, the seventh routing tier 360 is at least partially (e.g., substantially) employed as a global routing tier (e.g., a second global routing tier), and at least some of the seventh routing structures 362 thereof are employed as global routing structures (e.g., second global routing structures). By way of non-limiting example, different seventh routing structures 362 of the seventh routing tier 360 may be employed as column select (CS) routing structures and/or jump routing structures (e.g., between horizontally neighboring control circuitry regions 302). The seventh routing structures 362 of the seventh routing tier 360 may individually be formed of and include conductive material. In some embodiments, the seventh routing structures 362 of the seventh routing tier 360 are individually formed of and include one or more of W, Cu, Ru, Mo, and TiN.

Within the eighth routing tier 364, the eighth routing structures 366 thereof may be employed for various other operational functions of the microelectronic device 100. Operational functions facilitated by the eighth routing structures 366 of the eighth routing tier 364 may be at least partially different than the operational functions facilitated by the fourth routing structures 340 of the fourth routing tier 338, the fifth routing structures 354 of the fifth routing tier 352, and the sixth routing structures 358 of the sixth routing tier 356. In some embodiments, the eighth routing tier 364 is at least partially (e.g., substantially) employed as a global routing tier (e.g., a third global routing tier), and at least some of the eighth routing structures 366 thereof are employed as global routing structures (e.g., third global routing structures). In some such embodiments, operational functions facilitated by the eighth routing structures 366 of the eighth routing tier 364 are similar to those facilitated by the seventh routing structures 362 of the seventh routing tier 360. For example, different eighth routing structures 366 of the eighth routing tier 364 may be employed as additional CS routing structures. In additional embodiments, operational functions facilitated by the eighth routing structures 366 of the eighth routing tier 364 are different than those facilitated by the seventh routing structures 362 of the seventh routing tier 360. For example, different eighth routing structures 366 of the eighth routing tier 364 may be employed as various power routing structures (also referred to herein as “power delivery network” routing structures) for the microelectronic device 100. The eighth routing structures 366 of the eighth routing tier 364 may individually be formed of and include conductive material. In some embodiments, the eighth routing structures 366 of the eighth routing tier 364 are individually formed of and include one or more of W, Cu, Ru, Mo, and TiN.

Within the ninth routing tier 368, the ninth routing structures 370 thereof may be employed for various, yet additional operational functions of the microelectronic device 100. Operational functions facilitated by the ninth routing structures 370 of the ninth routing tier 368 may be at least partially different than the operational functions facilitated by the fourth routing structures 340 of the fourth routing tier 338, the fifth routing structures 354 of the fifth routing tier 352, the sixth routing structures 358 of the sixth routing tier 356, the seventh routing structures 362 of the seventh routing tier 360, and the eighth routing structures 366 of the eighth routing tier 364. The operational function facilitated by an individual ninth routing structure 370 may at least partially depend on the horizontal location of the ninth routing structure 370, as described in further detail below with reference to FIG. 10. In some embodiments, the ninth routing tier 368 is at least partially (e.g., substantially) employed as a global routing tier (e.g., a fourth global routing tier), and at least some of the ninth routing structures 370 thereof are employed as global routing structures (e.g., fourth global routing structures). By way of non-limiting example, different ninth routing structures 370 of the ninth routing tier 368 may be employed as various power routing structures (e.g., array voltage (V_{ARY}) routing structures, periphery voltage (V_{PERI}) routing structures, supply voltage (V_{CCP}) routing structures, ground (V_{SS}) routing structures, equilibrium voltage (V_{EQ}) routing structures, negative word line voltage (V_{NWL}) routing structures, voltage active time delay (V_{ACTD}) routing structures, voltage below precharge (V_{BLP}) routing structures, sense amplifier isolation (V_{ISOSA}) routing structures) for the microelectronic device 100. The ninth routing structures 370 of the ninth routing tier 368 may individually be formed of and include conductive material. In some embodiments, the ninth routing structures 370 of the ninth routing tier 368 are individually formed of and include one or more of W, Cu, Ru, Mo, and TiN.

Within the tenth routing tier 372, the tenth routing structures 374 thereof may be employed for various, yet further operational functions of the microelectronic device 100. Operational functions facilitated by the tenth routing structures 374 of the tenth routing tier 372 may be at least partially different than the operational functions facilitated by the fourth routing structures 340 of the fourth routing tier 338, the fifth routing structures 354 of the fifth routing tier 352, the sixth routing structures 358 of the sixth routing tier 356, the seventh routing structures 362 of the seventh routing tier 360, the eighth routing structures 366 of the eighth routing tier 364, and the ninth routing structures 370 of the ninth routing tier 368. The operational function facilitated by an individual tenth routing structure 374 may at least partially depend on the horizontal location of the tenth routing structure 374, as described in further detail below with reference to FIG. 10. In some embodiments, the tenth routing tier 372 is at least partially (e.g., substantially) employed as a global routing tier (e.g., a fifth global routing tier), and at least some of the tenth routing structures 374 thereof are employed as global routing structures (e.g., fifth global routing structures). By way of non-limiting example, different tenth routing structures 374 of the tenth routing tier 372 may be employed as various global input/output routing structures (also referred to herein as “main input/output” routing structures) for the microelectronic device 100. The tenth routing structures 374 of the tenth routing tier 372 may individually be formed of and include conductive material. In some embodiments, the tenth routing structures 374 of the tenth routing tier 372 are individually formed of and include one or more of W, Cu, Al, Ru, Mo, and TiN.

A further isolation material 376 may be formed on or over portions of at least the control logic devices 344 (including the transistors 324, the third contact structure 342, and the fourth routing structures 340 thereof), the fourth contact structures 350, and the additional routing structures (e.g., the fifth routing structures 354, the sixth routing structures 358, the seventh routing structures 362, the eighth routing structures 366, the ninth routing structures 370, the tenth routing structures 374). The further isolation material 376 may be formed of and include insulative material. In some embodiments, the further isolation material 376 is formed of and includes a dielectric oxide material, such as SiOₓ (e.g., SiO₂). The further isolation material 376 may be substantially homogeneous, or the further isolation material 376 may be heterogeneous.

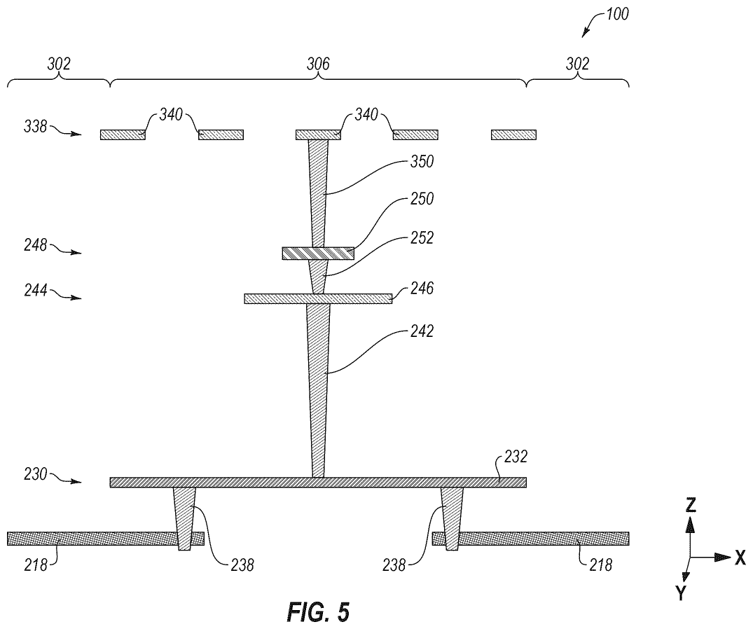

Referring next to FIG. 5, in accordance with some embodiments of the disclosure, illustrated is a portion of the microelectronic device 100 encompassing two (2) control circuitry regions 302 (and, hence, two (2) array regions 202 (FIG. 2)) horizontally neighboring one another in the X-direction, as well as an individual word line contact region 306 (and, hence, word line exit region 206 (FIG. 2)) therebetween. As shown in FIG. 5, the microelectronic device 100 may be configured such that an individual first routing structure 232 of the first routing tier 230, an individual first contact structure 242, an individual second routing structure 246 of the second routing tier 244, an individual second contact structure 252 (if any), an individual third routing structure 250 (if any) of the third routing tier 248 (if any), and an individual fourth contact structure 350 are respectively and in combination shared between the two (2) control circuitry regions 302 (and respective two (2) array regions 202 (FIG. 2)) of the microelectronic device 100. The first routing structure 232 may be coupled to one word line structure 218 within a horizontal area of one of the two (2) control circuitry regions 302 and another word line structure 218 within a horizontal area of another of the two (2) control circuitry regions 302 by way of two (2) word line contact structures 238; and may horizontally extend, in the X-direction, through the word line contact region 306. Within the word line contact region 306, the first contact structure 242 may vertically overlie and contact the first routing structure 232, the second routing structure 246 may vertically overlie and contact the first contact structure 242, the second contact structure 252 may vertically overlie and contact the second routing structure 246, the third routing structure 250 may vertically overlie and contact the second contact structure 252, and the fourth contact structure 350 may vertically overlie and contact the third routing structure 250. In addition, fourth routing structures 340 of the fourth routing tier 338 may vertically overly and be coupled to the fourth contact structure 350 and may horizontally extend into the two (2) control circuitry regions 302. The fourth routing structures 340 may be coupled to control logic devices 344 (FIG. 4) (e.g., SWD devices 348 (FIG. 4)) within the two (2) control circuitry regions 302. Sharing the forementioned features of the microelectronic device 100 may permit the word line contact region 306 (and the respective word line exit region 206 (FIG. 2)) to have a relatively smaller horizontal area than may otherwise exhibited in the absence of such shared features. For example, a horizontal dimension, in the X-direction, of the word line contact region 306 (and a respective word line exit region 206 (FIG. 2)) may be about one-half (½) a horizontal dimension, if the Y-direction, of an individual digit line contact region 304 (FIG. 2) (and a respective digit line exit region 204 (FIG. 2)) of the microelectronic device 100.

In additional embodiments, the microelectronic device 100 may be configured such that first routing structures 232 of the first routing tier 230, first contact structures 242, second routing structures 246 of the second routing tier 244, second contact structures 252 (if any), third routing structures 250 (if any) of the third routing tier 248 (if any), and fourth contact structures 350 are not shared between control circuitry regions 302 (and respective two (2) array regions 202 (FIG. 2)) horizontally neighboring one another in the X-direction. Two (2) first routing structure 232, isolated from one another, may respectively horizontally extend (e.g., in the X-direction) into the horizontal area of the word line contact region 306 (and a respective word line exit region 206 (FIG. 2)), and may individually include a first contact structure 242, a second routing structure 246, a second contact structure 252 (if any), a third routing structure 250 (if any), a fourth contact structure 350 vertically overlying and coupled therewith. Accordingly, the word line contact region 306 (and the respective word line exit region 206 (FIG. 2)) may include a pair of the first routing structures 232 of the first routing tier 230, a pair of the first contact structures 242, a pair of the second routing structures 246 of the second routing tier 244, a pair of second contact structures 252 (if any), a pair of the third routing structures 250 (if any) of the third routing tier 248 (if any), and a pair of the fourth contact structures 350 within the horizontal area thereof. As a result, the word line contact region 306 (and the respective word line exit region 206 (FIG. 2)) may have a relatively horizontal area than may otherwise be facilitated by way of the feature sharing described above with reference to FIG. 5. For example, a horizontal dimension, in the X-direction, of the word line contact region 306 (and a respective word line exit region 206 (FIG. 2)) may be about equal to (e.g., about the same as) a horizontal dimension, if the Y-direction, of an individual digit line contact region 304 (FIG. 2) (and a respective digit line exit region 204 (FIG. 2)) of the microelectronic device 100.

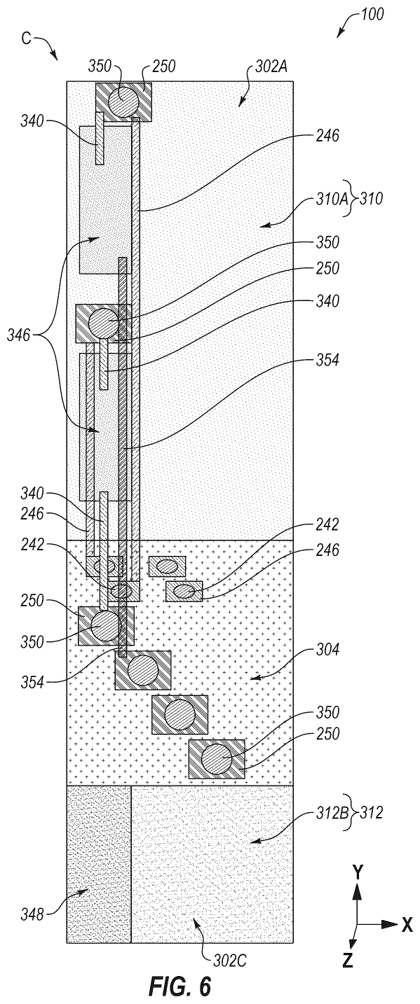

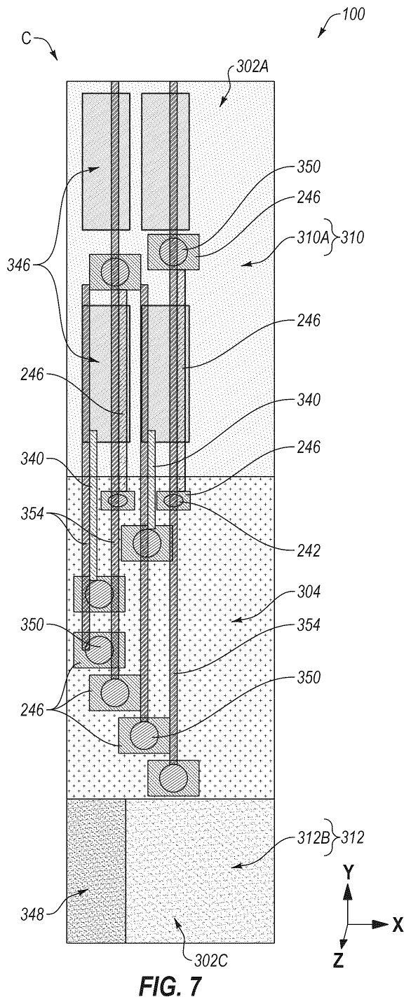

FIGS. 6 and 7 are simplified, partial top-down views of the microelectronic device 100 collectively shown in FIGS. 1 through 4, taken about dashed box C shown in FIG. 3, showing different feature (e.g., region, sub-region, contact structure, routing structure, control logic device) configurations within a portion of the microelectronic device 100, in accordance with some embodiments of the disclosure. For example, as described in further detail below, FIGS. 6 and 7 show different configurations, within a horizontal area of the dash box C depicted in FIG. 3, of some of the first contact structures 242, some of the second routing structures 246, some of the second contact structures 252 (if any), some of the third routing structures 250 (if any), some of the fourth contact structures 350, some of the fourth routing structures 340, some of the SA devices 346, and some of the SWD devices 348 positioned within different regions and sub-regions of the microelectronic device 100. Such feature configurations may be employed to couple some of the memory cells 236 (FIG. 4) of the memory array structure 200 (FIG. 4) to some of the SA devices 346 of the control circuitry structure 300 (FIG. 4). For clarity and case of understanding of the drawings and related description, not all features of the microelectronic device 100 depicted in one or more of FIGS. 1 through 4 are depicted in FIGS. 6 and 7. For example, some features of the microelectronic device 100 vertically overlying or vertically underlying other features of the microelectronic device 100 are not shown in one or more of FIGS. 6 and 7 so as to provide a clearer view of the other features.

Referring first to FIG. 6, SA devices 346 (e.g., even SA devices, odd SA devices) within the first SA sub-region 310A of the first control circuitry region 302A may be coupled to some of the digit line structures 224 (FIG. 4) (e.g., even digit line structures, odd digit line structures) of the memory array structure 200 (FIG. 4) through a combination of the first routing structures 232 (FIG. 4), the first contact structures 242, the second routing structures 246, the second contact structures 252 (FIG. 4), the third routing structures 250, the fourth contact structures 350, the fourth routing structures 340, and the fifth routing structures 354. Some of, and/or some portions of, the first routing structures 232 (FIG. 4), the first contact structures 242, the second routing structures 246, the second contact structures 252 (FIG. 4), the third routing structures 250, the fourth contact structures 350, the fourth routing structures 340, and the fifth routing structures 354 coupled to the SA devices 346 may be positioned within the horizontal area of the digit line contact region 304. Some others of, and/or some other portions of, the first routing structures 232 (FIG. 4), the first contact structures 242, the second routing structures 246, the second contact structures 252 (FIG. 4), the third routing structures 250, the fourth contact structures 350, the fourth routing structures 340, and the fifth routing structures 354 coupled to the SA devices 346 may be positioned within the horizontal area of the first SA sub-region 310A.

As shown in FIG. 6, for an individual SA device 346 within the first SA sub-region 310A and located relatively horizontally closer (e.g., in the Y-direction) to the digit line contact region 304, a first combination of one of the first contact structures 242, one of the second routing structures 246, one of the second contact structures 252 (FIG. 4), one of the third routing structures 250, one of the fourth contact structures 350, and one of the fourth routing structures 340 may route and be coupled to one end (in the Y-direction) of the SA device 346 relatively farther from the digit line contact region 304; and a second combination of another one of the first contact structures 242, another one of the second routing structures 246, another one of the second contact structures 252 (FIG. 4), another one of the third routing structures 250, another one of the fourth contact structures 350, and another one of the fourth routing structures 340 may route and be coupled to another, opposite end (in the Y-direction) of the SA device 346 relatively closer to the digit line contact region 304. For the first combination, the one of the first contact structures 242 and a portion of the one of the second routing structures 246 thereof may be positioned within the digit line contact region 304; and an additional portion of the one of the second routing structures 246, the one of the second contact structures 252 (FIG. 4), the one of the third routing structures 250, the one of the fourth contact structures 350, and the one of the fourth routing structures 340 thereof may be positioned within the first SA sub-region 310A. For the second combination, the another one of the first contact structures 242, the another one of the second routing structures 246, the another one of the second contact structures 252 (FIG. 4), the another one of the third routing structures 250, the another one of the fourth contact structures 350, and a portion of the another one of the fourth routing structures 340 thereof may be positioned within the digit line contact region 304; and an additional portion of the another one of the fourth routing structures 340 thereof may be positioned within the first SA sub-region 310A.

Still referring to FIG. 6, for another individual SA device 346 within the first SA sub-region 310A and located relatively horizontally farther (e.g., in the Y-direction) from the digit line contact region 304, a third combination of an additional one of the first contact structures 242, an additional one of the second routing structures 246, an additional one of the second contact structures 252 (FIG. 4), an additional one of the third routing structures 250, an additional one of the fourth contact structures 350, and an additional one of the fourth routing structures 340 may route and be coupled to one end (in the Y-direction) of the SA device 346 relatively farther from the digit line contact region 304; and a fourth combination of a further one of the first contact structures 242, a further one of the second routing structures 246, a further one of the second contact structures 252 (FIG. 4), a further one of the third routing structures 250, a further one of the fourth contact structures 350, a further one of the fourth routing structures 340, and one of the fifth routing structures 354 may route and be coupled to another, opposite end (in the Y-direction) of the SA device 346 relatively closer to the digit line contact region 304. For the third combination, the additional one of the first contact structures 242 and a portion of the additional one of the second routing structures 246 thereof may be positioned within the digit line contact region 304; and an additional portion of the additional one of the second routing structures 246, the additional one of the second contact structures 252 (FIG. 4), the additional one of the third routing structures 250, the additional one of the fourth contact structures 350, and the additional one of the fourth routing structures 340 thereof may be positioned within the first SA sub-region 310A. For the fourth combination, the further one of the first contact structures 242, the further one of the second routing structures 246, the further one of the second contact structures 252 (FIG. 4), the further one of the third routing structures 250, the further one of the fourth contact structures 350, the further one of the fourth routing structures 340, and a portion of the one of the fifth routing structures 354 thereof may be positioned within the digit line contact region 304; and an additional portion of the one of the fifth routing structures 354 thereof may be positioned within the first SA sub-region 310A.

In some embodiments, first routing and contact groups are coupled to a group of the digit line structures 224 (FIG. 4) employed as so-called “base” digit line structures (e.g., true digit line structures); and second routing and contact groups are coupled to an additional group of the digit line structures 224 (FIG. 4) employed as so-called “complementary” digit line structures (e.g., digit bar line structures); or vice versa. The first routing and contact groups may respectively include at least one first routing structure 232 (FIG. 4), at least one first contact structure 242, at least one second routing structure 246, at least one third routing structure 250, at least one second contact structure 252 (FIG. 4), and at least one fourth contact structure 350. The second routing and contact groups may respectively include at least one other first routing structure 232 (FIG. 4), at least one other first contact structure 242, at least one other second routing structure 246, at least one other third routing structure 250, at least one other second contact structure 252 (FIG. 4), and at least one other fourth contact structure 350. As a non-limiting example, if an individual first SA sub-region 310A includes odd SA devices 346, the first routing and contact groups may be coupled to a group of the digit line structures 224 (FIG. 4) employed as odd base digit line structures; and the second routing and contact groups may be coupled to an additional group of the digit line structures 224 (FIG. 4) employed as odd complementary digit line structures; or vice versa. As another non-limiting example, if an individual first SA sub-region 310A includes even SA devices 346, the first routing and contact groups may be coupled to a group of the digit line structures 224 (FIG. 4) employed as so-called even base digit line structures; and the second routing and contact groups may be coupled to an additional group of the digit line structures 224 (FIG. 4) employed as even complementary digit line structures; or vice versa.

Referring next to FIG. 7, the depicted configuration may have some similarity to that previously described with reference to FIG. 6, but the third routing structures 250 (FIG. 6) and the second contact structures 252 (FIG. 4) may be omitted. SA devices 346 (e.g., even SA devices, odd SA devices) within the first SA sub-region 310A of the first control circuitry region 302A may be coupled to some of the digit line structures 224 (FIG. 4) (e.g., even digit line structures, odd digit line structures) of the memory array structure 200 (FIG. 4) through a combination of the first routing structures 232 (FIG. 4), the first contact structures 242, the second routing structures 246, the fourth contact structures 350, the fourth routing structures 340, and the fifth routing structures 354. In view of the omission of the third routing structures 250 (FIG. 6) and the second contact structures 252 (FIG. 4), rather than vertically extending to and contacting the third routing structures 250 (FIG. 6), the fourth contact structures 350 may vertically extend to and contact the second routing structures 246. For example, an individual fourth contact structure 350 may vertically extend from individual second routing structure 246 to an individual fourth routing structure 340 or an individual fifth routing structure 354. As shown in FIG. 7, as a result of the omission of the third routing structures 250 (FIG. 6) and the second contact structures 252 (FIG. 4), pairs of the fifth routing structures 354 are employed to route from some of the fourth contact structures 350 within the digit line contact region 304 to ends (e.g., in the Y-direction) of the SA devices 346. The configuration shown in FIG. 7 may result in a horizontal dimension in the Y-direction of the digit line contact region 304 (and, hence, a horizontal dimension of the associated digit line exit region 204 (FIG. 4)) being relatively larger than a horizontal dimension in the Y-direction of the digit line contact region 304 for the configurations previously described herein with reference to FIG. 6.

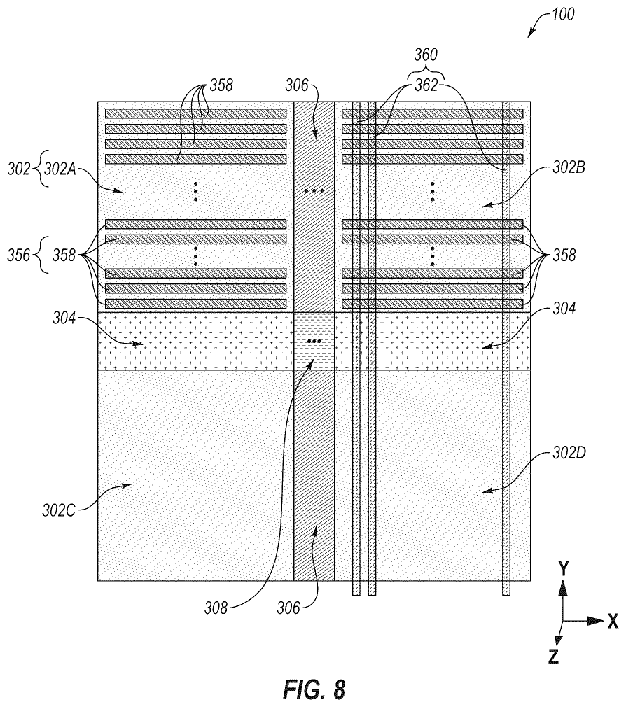

Referring collectively FIGS. 8 and 9, depicted are simplified, partial schematic views a portion of the microelectronic device 100 collectively shown in FIGS. 1 through 4, showing various routing structures at different vertical elevations within the microelectronic device 100, in accordance with some embodiments of the disclosure. FIG. 8 shows configurations of the sixth routing structures 358 of the sixth routing tier 356 and the seventh routing structures 362 of the seventh routing tier 360 within the microelectronic device 100. For clarity and case of understanding of the drawings and related description, within the portion of the microelectronic device 100 shown in FIG. 8, only some of the sixth routing structures 358 of the sixth routing tier 356 and only some of seventh routing structures 362 of the seventh routing tier 360 are shown so as to provide a clearer view of various features of the microelectronic device 100. FIG. 9 shows configurations of the eighth routing structures 366 of the eighth routing tier 364, the ninth routing structures 370 of the ninth routing tier 368, and the tenth routing structures 374 of the tenth routing tier 372 within the microelectronic device 100. For clarity and ease of understanding of the drawings and related description, within the portion of the microelectronic device 100 shown in FIG. 9, only some of the eighth routing structures 366 of the eighth routing tier 364, only some of the ninth routing structures 370 of the ninth routing tier 368, and only some of the tenth routing structures 374 of the tenth routing tier 372 are shown so as to provide a clearer view of various features of the microelectronic device 100.

Referring first to FIG. 8, within horizontal areas of the control circuitry regions 302 of the microelectronic device 100, the sixth routing structures 358 of the sixth routing tier 356 may horizontally extend in parallel in the X-direction. At least some of the sixth routing structures 358 of the sixth routing tier 356 (e.g., sixth routing structures 358 respectively employed as MWL control signal routing structures, local input/output routing structures, or SA control signal routing structures) may individually be substantially confined within a horizonal area of a respective control circuitry region 302. For example, as shown in FIG. 8, a first group of the sixth routing structures 358 may be substantially confined within a horizontal area of the first control circuitry region 302A, and a second group of the sixth routing structures 358 may be substantially confined within a horizontal area of the second control circuitry region 302B. Some additional routing structures (e.g., some eighth routing structures 366 (FIG. 4), some ninth routing structures 370 (FIG. 4)) of one or more of the additional routing tiers (e.g., the eighth routing tier 364 (FIG. 4), the ninth routing tier 368 (FIG. 4)) may be employed as jump structures to couple some sixth routing structures 358 (e.g., MWL control signal routing structures) within one of the control circuitry regions 302 (e.g., the first control circuitry region 302A) to some other sixth routing structures 358 (e.g., additional MWL control signal routing structures) within a horizontally neighboring one of the control circuitry regions 302 (e.g., the second control circuitry region 302B).

Still referring to FIG. 8, the seventh routing structures 362 of the seventh routing tier 360 may horizontally extend in parallel in the Y-direction. Accordingly, the seventh routing structures 362 of the seventh routing tier 360 may respectively horizontally extend orthogonal to the direction (e.g., the X-direction) of the sixth routing structures 358 of the sixth routing tier 356. At least some of the seventh routing structures 362 of the seventh routing tier 360 (e.g., seventh routing structures 362 employed as CS routing structures) may continuously extend in the Y-direction over multiple control circuitry regions 302 horizontally neighboring one another in the Y-direction (e.g., the first control circuitry region 302A and the third control circuitry region 302C; the second control circuitry region 302B and the fourth control circuitry region 302D) as well as the digit line contact region 304 horizontally interposed therebetween.

Referring next to FIG. 9, the eighth routing structures 366 of the eighth routing tier 364 may horizontally extend in parallel in the Y-direction. Accordingly, the eighth routing structures 366 of the eighth routing tier 364 may respectively horizontally extend in the same direction (e.g., the Y-direction) as the seventh routing structures 362 (FIG. 8) of the seventh routing tier 360 (FIG. 8) and may respectively horizontally extend orthogonal to the direction (e.g., the X-direction) the sixth routing structures 358 (FIG. 8) of the sixth routing tier 356 (FIG. 8). At least some of the eighth routing structures 366 of the eighth routing tier 364 (e.g., eighth routing structures 366 employed as additional CS routing structures) may continuously extend in the Y-direction over multiple control circuitry regions 302 horizontally neighboring one another in the Y-direction (e.g., the first control circuitry region 302A and the third control circuitry region 302C; the second control circuitry region 302B and the fourth control circuitry region 302D) as well as the digit line contact region 304 horizontally interposed therebetween.

Still referring to FIG. 9, the ninth routing structures 370 of the ninth routing tier 368 may horizontally extend in parallel in the X-direction. Accordingly, the ninth routing structures 370 of the ninth routing tier 368 may respectively horizontally extend in the same direction (e.g., the X-direction) as the sixth routing structures 358 (FIG. 8) of the sixth routing tier 356 (FIG. 8), and may respectively horizontally extend orthogonal to the direction (e.g., the Y-direction) of the seventh routing structures 362 (FIG. 8) of the seventh routing tier 360 (FIG. 8) and the eighth routing structures 366 of the eighth routing tier 364. At least some of the ninth routing structures 370 of the ninth routing tier 368 (e.g., ninth routing structures 370 respectively employed as power routing structures, such as V_{ARY} routing structures, V_{PERI} routing structures, V_{CCP} routing structures, V_{SS} routing structures, V_{EQ} routing structures, V_{NWL} routing structures, V_{ACTD} routing structures, V_{BLP} routing structures, V_{ISOSA} routing structures) may individually be substantially confined within a horizonal area of a respective control circuitry region 302. For example, as shown in FIG. 8, a first group of the ninth routing structures 370 may be substantially confined within a horizontal area of the first control circuitry region 302A, and a second group of the ninth routing structures 370 may be substantially confined within a horizontal area of the second control circuitry region 302B.

Still referring to FIG. 9, the tenth routing structures 374 of the tenth routing tier 372 may horizontally extend in parallel in the Y-direction. Accordingly, the tenth routing structures 374 of the tenth routing tier 372 may respectively horizontally extend in the same direction (e.g., the Y-direction) as the seventh routing structures 362 (FIG. 8) of the seventh routing tier 360 (FIG. 8) and the eighth routing structures 366 of the eighth routing tier 364, and may respectively horizontally extend orthogonal to the direction (e.g., the X-direction) of the sixth routing structures 358 (FIG. 8) of the sixth routing tier 356 (FIG. 8) and the ninth routing structures 370 of the ninth routing tier 368. At least some of the tenth routing structures 374 of the tenth routing tier 372 (e.g., tenth routing structures 374 employed as global input/output routing structures) may continuously extend in the Y-direction over multiple control circuitry regions 302 horizontally neighboring one another in the Y-direction (e.g., the first control circuitry region 302A and the third control circuitry region 302C; the second control circuitry region 302B and the fourth control circuitry region 302D) as well as the digit line contact region 304 horizontally interposed therebetween.

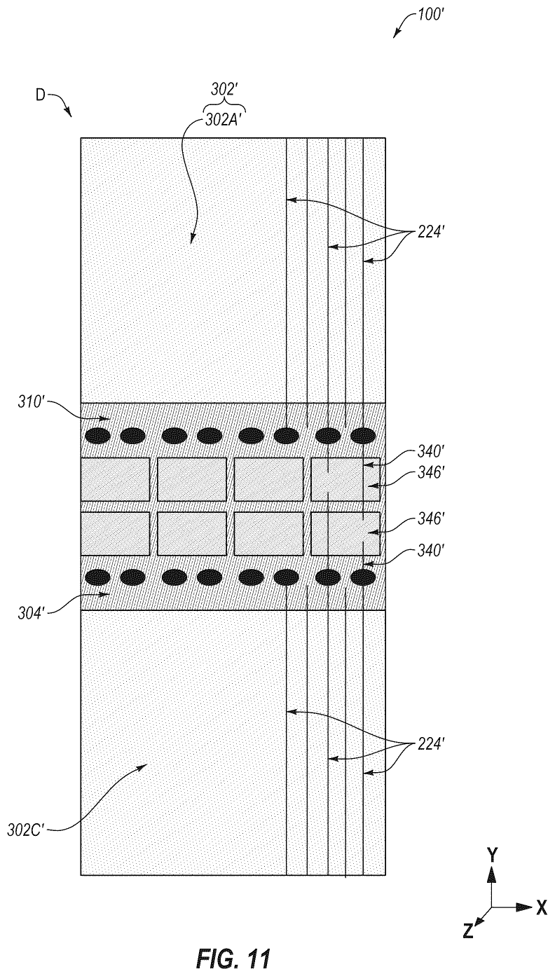

As previously described herein, in additional embodiments, the control circuitry structure 300 of the microelectronic device 100 may be formed to exhibit a different configuration than that previously described herein with reference to FIGS. 3 and 4. For example, FIG. 10 is a simplified, partial schematic view of a control circuitry structure 300′ for the microelectronic device 100 depicted in FIG. 1, in accordance with some additional embodiments of the disclosure. The control circuitry structure 300′ may be employed in place of the control circuitry structure 300 previously described herein with reference to FIGS. 3 and 4. The control circuitry structure 300′ may have a so-called “non-quilt” arrangement of different control logic circuitry (e.g., SA circuitry, SWD circuitry) thereof, as described in further detail below. To avoid repetition, not all features shown in FIG. 10 are described in detail herein. Rather, in FIG. 10, as well as subsequent FIGS. 11 through 13, unless otherwise described hereafter, a feature (e.g., region, sub-region, material, structure, device) designated by a reference numeral that as a prime (′) of a reference numeral of a previously described feature.

As shown in FIG. 10, the control circuitry structure 300′ may exhibit a similar arrangement of control circuitry regions 302′, digit line contact regions 304′, and word line contact regions 306′ as that previously described, with reference to FIGS. 3 and 4, in relation to the arrangement of the control circuitry regions 302, the digit line contact regions 304, and the word line contact regions 306 of the control circuitry structure 300. In addition, within the microelectronic device 100′ including the memory array structure 200 (FIGS. 1, 2, and 4) and the control circuitry structure 300′, the control circuitry regions 302′, digit line contact regions 304′, and word line contact regions 306′ are configured to at least partially (e.g., substantially) horizontally overlap the array regions 202 (FIG. 2), the digit line exit regions 204 (FIG. 2), and the word line exit regions 206 (FIG. 2) of the memory array structure 200 (FIG. 2), respectively. However, unlike the configuration of the control circuitry structure 300 (FIG. 3) previously described herein, the SA sub-regions 310′ and the SWD sub-regions 312′ of the control circuitry structure 300′ are positioned outside of the horizontal areas of the control circuitry regions 302′ (and, hence, the array regions 202 of the memory array structure 200). The SA sub-regions 310′ of the control circuitry structure 300′ may be at least partially (e.g., substantially) positioned within horizontal areas of the digit line contact regions 304′ of the control circuitry structure 300′ (and, hence, within horizontal areas of the digit line exit regions 204 of the memory array structure 200). The SWD sub-regions 312′ of the control circuitry structure 300′ may be at least partially (e.g., substantially) positioned within horizontal areas of the word line contact regions 306′ of the control circuitry structure 300′ (and, hence, within horizontal areas of the word line exit regions 206 of the memory array structure 200).

Referring collectively to FIGS. 4 and 10, the control circuitry structure 300′ may include similar features (e.g., structures, materials, devices) to those of the control circuitry structure 300 previously described with reference to FIG. 4, but whereas the control circuitry structure 300 includes the SA devices 346 and the SWD devices 348 within horizontal areas of the control circuitry regions 302 thereof (and, hence, within the horizontal areas of the array regions 202 of the memory array structure 200), corresponding SA devices and corresponding SWD devices the control circuitry structure 300′ are positioned within the horizontal areas of the digit line contact regions 304′ (and, hence, the digit line exit region 204 of the memory array structure 200) and the word line contact regions 306′ (and, hence, the digit line exit region 204 of the memory array structure 200), respectively. As a result, some of the routing structures (e.g., second routing structures 246, third routing structures 250, fourth routing structures 340) and some of the contact structures (e.g., second contact structures 252, fourth contact structures 350) employed to horizontally route to the SA devices 346 and the SWD devices 348 within the control circuitry structure 300 may be configured differently within the control circuitry structure 300′.

Referring next to FIG. 11, depicted is simplified, partial top-down view of the microelectronic device 100′ collectively depicted by way of FIGS. 1, 2, 4, and 10, taken about dashed box D shown in FIG. 11, showing different feature (e.g., region, sub-region, contact structure, routing structure, control logic device) configurations within a portion of the microelectronic device 100′, in accordance with some embodiments of the disclosure. For example, as described in further detail below, FIG. 11 shows a configuration, within a horizontal area of the dash box D depicted in FIG. 10, of some of the SA devices 346′, some of the digit line structures 224′, and various routing and contact structures within different regions (e.g., a digit line contact region 304′, control circuitry regions 302′) control and sub-regions (e.g., SA sub-region 310′ within the digit line contact region 304′) of the microelectronic device 100′. Such feature configurations may be employed to couple some of the memory cells 236 (FIG. 4) of the memory array structure 200 (FIG. 4) to some of the SA devices 346′ of the control circuitry structure 300′ (FIG. 10). For clarity and ease of understanding of the drawings and related description, not all features of the microelectronic device 100′ depicted in one or more of FIGS. 1, 2, 4, and 10 are depicted in FIG. 10. For example, some features of the microelectronic device 100′ vertically overlying or vertically underlying other features of the microelectronic device 100′ are not shown in one or more of FIG. 10 so as to provide a clearer view of the other features.

As shown in FIG. 11, within an individual SA sub-region 310′ within a horizontal area of an individual digit line contact region 304′, the SA devices 346′ may be horizontally positioned relative to one another in a so-called “stacked” arrangement. The stacked arrangement may include multiple “stacked” pairs of the SA devices 346′. For each stacked pair of the SA devices 346′, the two SA devices 346′ thereof may horizontally neighbor one another in the Y-direction, and may substantially horizontally overlap (e.g., be substantially horizontally aligned with) one another in the X-direction. An individual pair of the SA devices 346′ may include a first of the SA devices 346′ horizontally positioned, in the Y-direction, relatively more horizontally proximate one of the control circuitry regions 302′ (e.g., the first control circuitry region 302A); and a second of the SA devices 346′ horizontally positioned, in the Y-direction, relatively more horizontally proximate another one of the control circuitry regions 302′ (e.g., the third control circuitry region 302C′). The first of the SA devices 346′ may be coupled to some of the digit line structures 224′ of the memory array structure 200 (FIG. 4) through two (2) combinations of routing and contact structures; and the second of the SA devices 346′ may be coupled to some other of the digit line structures 224′ of the memory array structure 200 (FIG. 4) through two (2) additional combinations routing and contact structures. Each of the two (2) combinations of routing and contact structures and each of the two (2) additional combinations of routing and contact structures may respectively include features corresponding to the first routing structures 232, the first contact structures 242, the second routing structures 246, the second contact structures 252, the third routing structures 250, the fourth contact structures 350 previously described herein with reference to FIG. 4, as well as the fourth routing structures 340′ shown in FIG. 11. The two (2) combinations of routing and contact structures and the two (2) additional combinations of routing and contact structures may all be positioned within a horizontal area of the digit line contact region 304′.

With respect to a stacked pair of SA devices 346′ within an individual SA sub-region 310′, for an individual SA device 346′ thereof located relatively horizontally closer (e.g., in the Y-direction) to the first control circuitry region 302A′, a first of two (2) combinations of routing and contact structures may couple the SA device 346′ to one of the digit line structures 224′ horizontally extending through the first control circuitry region 302A′; and a second of the two (2) combinations of routing and contact structures may couple the SA device 346′ to an additional one of the digit line structures 224′ horizontally extending through the third control circuitry region 302C′. The first of the two (2) combinations of routing and contact structures may route to a first side of the SA device 346′ in the Y-direction, and the second of the two (2) combinations of routing and contact structures may route to a second, opposing side of the SA device 346′ in the Y-direction.

Still referring to FIG. 11, with respect to a stacked pair of SA devices 346′ within the SA sub-region 310′, for an additional individual SA device 346′ located relatively horizontally closer (e.g., in the Y-direction) to the third control circuitry region 302C′, a first of two (2) additional combinations of routing and contact structures may couple the SA device 346′ to another one of the digit line structures 224′ horizontally extending through the first control circuitry region 302A′; and a second of the two (2) combinations of routing and contact structures may couple the SA device 346′ to a further one of the digit line structures 224′ horizontally extending through the third control circuitry region 302C′. The first of the two (2) additional combinations of routing and contact structures may route to a first side of the SA device 346′ in the Y-direction, and the second of the two (2) additional combinations of routing and contact structures may route to a second, opposing side of the SA device 346′ in the Y-direction.

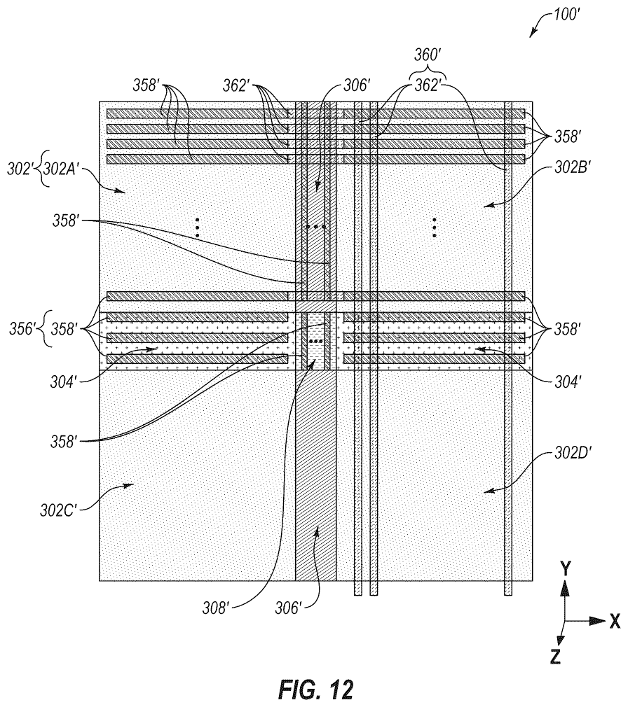

Referring next to FIG. 12, depicted is simplified, partial schematic view a portion of the microelectronic device 100′ collectively depicted by way of FIGS. 1, 2, 4, and 10, showing various routing structures at different vertical elevations within the microelectronic device 100′, in accordance with some embodiments of the disclosure. FIG. 12 shows configurations of the sixth routing structures 358′ of the sixth routing tier 356′ and the seventh routing structures 362′ of the seventh routing tier 360′ within the microelectronic device 100′. For clarity and case of understanding of the drawings and related description, within the portion of the microelectronic device 100′ shown in FIG. 12, only some of the sixth routing structures 358′ of the sixth routing tier 356′ and only some of seventh routing structures 362′ of the seventh routing tier 360′ are shown so as to provide a clearer view of various features of the microelectronic device 100′.

Within horizontal areas of the control circuitry regions 302′ of the microelectronic device 100′, some (e.g., groups) of the sixth routing structures 358′ of the sixth routing tier 356′ may horizontally extend in parallel in the X-direction. At least some of the sixth routing structures 358′ of the sixth routing tier 356′ (e.g., sixth routing structures 358 respectively employed as MWL control signal routing structures) may individually be substantially confined within a horizonal area of a respective control circuitry region 302. For example, as shown in FIG. 12, a first group of the sixth routing structures 358′ may be substantially confined within a horizontal area of the first control circuitry region 302A ‘, and a second group of the sixth routing structures 358’ may be substantially confined within a horizontal area of the second control circuitry region 302B′. In addition, within horizontal areas of the digit line contact regions 304′, others (e.g., additional groups) of the sixth routing structures 358′ of the sixth routing tier 356′ may horizontally extend in parallel in the Y-direction orthogonal to the X-direction. At least some of the others of the sixth routing structures 358′ of the sixth routing tier 356′ (e.g., sixth routing structures 358 respectively employed as SA control signal routing structures, sixth routing structures 358 respectively employed as local input/output routing structures) may individually be substantially confined within a horizonal area of a respective digit line contact region 304′. Positioning the some others of the sixth routing structures 358′ within the horizonal areas of the digit line contact region 304′ may facilitate relatively relaxed pitch for the some of the sixth routing structures 358′ within the horizonal areas of the control circuitry regions 302′. In addition, within horizontal areas of the word line contact regions 306′ and the additional minigap regions 308′, yet others (e.g., further groups) of the sixth routing structures 358′ of the sixth routing tier 356′ may horizontally extend in parallel in the Y-direction orthogonal to the X-direction.

Still referring to FIG. 12, some of the seventh routing structures 362′ of the seventh routing tier 360′ may horizontally extend in parallel in the Y-direction. For example, some of the seventh routing structures 362′ of the seventh routing tier 360′ (e.g., seventh routing structures 362′ employed as CS routing structures) may continuously extend in the Y-direction over multiple control circuitry regions 302′ horizontally neighboring one another in the Y-direction (e.g., the first control circuitry region 302A′ and the third control circuitry region 302C′; the second control circuitry region 302B′ and the fourth control circuitry region 302D′) as well as the digit line contact region 304′ horizontally interposed therebetween. In addition, others of the seventh routing structures 362′ of the seventh routing tier 360′ within horizontal areas of the word line contact regions 306′ of the microelectronic device 100′, may horizontally extend in parallel in the X-direction. The others of the seventh routing structures 362′ may, for example, be employed as jump structures to couple some sixth routing structures 358′ (e.g., MWL control signal routing structures) within one of the control circuitry regions 302′ (e.g., the first control circuitry region 302A′) to some other sixth routing structures 358′ (e.g., additional MWL control signal routing structures) within a horizontally neighboring one of the control circuitry regions 302′ (e.g., the second control circuitry region 302B′).

Configurations of additional routing tiers and associated additional routing structures vertically overlying the seventh routing structures 362′ of the seventh routing tier 360′ may be substantially similar to those previously described herein with reference to FIG. 9. For example, additional routing structures of the microelectronic device 100′ may have configurations corresponding to (e.g., substantially the same as) those of the eighth routing structures 366 of the eighth routing tier 364, the ninth routing structures 370 of the ninth routing tier 368, and the tenth routing structures 374 of the tenth routing tier 372 of the microelectronic device 100 previously described herein with reference to FIGS. 4 and 9.

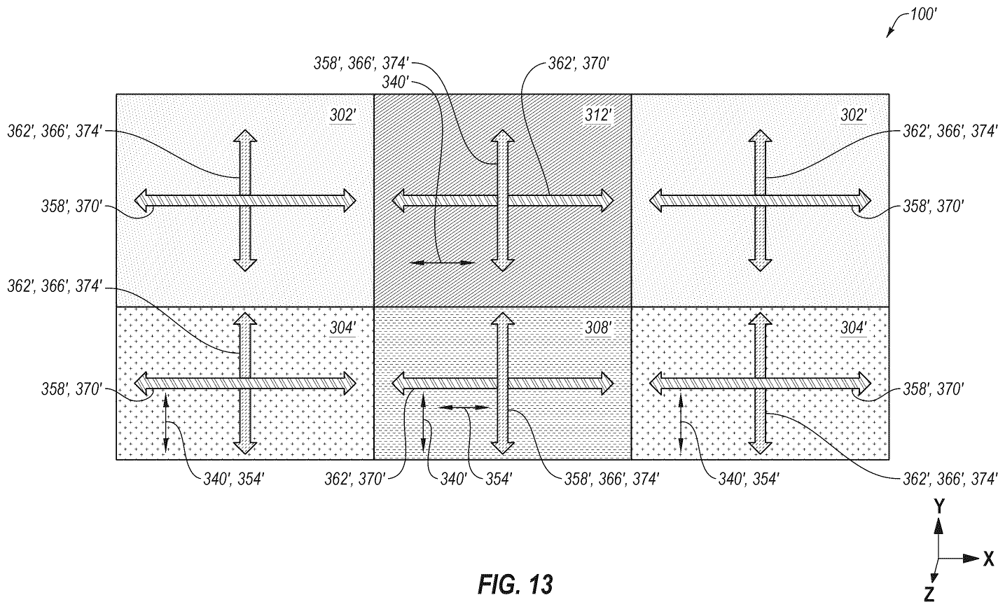

FIG. 13 is a simplified, partial schematic view a portion of the microelectronic device 100′ collectively depicted by way of FIGS. 1, 2, 4, and 10, showing horizontal directional paths and horizontal orientations of different routing structures of the microelectronic device 100′ within different regions of the microelectronic device 100′, in accordance with some embodiments of the disclosure. Within horizontal areas of the control circuitry regions 302′, the sixth routing structures 358′ and the ninth routing structures 370′ may respectively horizontally extend in the X-direction; and the seventh routing structures 362′, the eighth routing structures 366′, and the tenth routing structures 374′ may respectively horizontally extend in the Y-direction orthogonal to the X-direction. Within horizontal areas of the digit line contact regions 304′, the sixth routing structures 358′ and the ninth routing structures 370′ may respectively horizontally extend in the X-direction; and the fourth routing structures 340′, the fifth routing structures 354′, the seventh routing structures 362′, the eighth routing structures 366′, and the tenth routing structures 374′ may respectively horizontally extend in the Y-direction. Within horizontal areas of the additional minigap regions 308′, the fifth routing structures 354′, the seventh routing structures 362′, and the ninth routing structures 370′ may respectively horizontally extend in the X-direction; and the fourth routing structures 340′, the sixth routing structures 358′, the eighth routing structures 366′, and the tenth routing structures 374′ may respectively horizontally extend in the Y-direction. Within horizontal areas of the word line contact regions 306′, the fourth routing structures 340′, the seventh routing structures 362′, and the ninth routing structures 370′ may respectively horizontally extend in the X-direction; and the sixth routing structures 358′, the eighth routing structures 366′, and the tenth routing structures 374′ may respectively horizontally extend in the Y-direction.

Thus, in accordance with embodiments of the disclosure, a microelectronic device includes a memory array structure, a control circuitry structure, and global routing tiers. The memory array structure includes array regions respectively including volatile memory cells. The control circuitry structure is vertically above and bonded to the memory array structure. The control circuitry structure includes control circuitry regions horizontally overlapping the array regions and comprising control logic circuitry coupled to the volatile memory cells of the array regions. The global routing tiers vertically overlie the control logic circuitry of the control circuitry structure. Some of the global routing tiers respectively include groups of global routing structures confined within horizontal areas of the control circuitry regions of the control circuitry structure. The global routing structures of respective ones of the groups horizontally extend in parallel in a first direction. Some others of the global routing tiers respectively include additional groups of global routing structures extending beyond the horizontal areas of the control circuitry regions of the control circuitry structure. The global routing structures of respective ones of the additional groups horizontally extend in parallel in a second direction orthogonal to the first direction.

Furthermore, in accordance with embodiments of the disclosure, a memory device includes an array region comprising volatile memory cells, word lines coupled to the volatile memory cells, and digit lines coupled to the volatile memory cells; control logic circuitry vertically above and at least partially horizontally overlapping the array region; a socket region horizontally neighboring the array region in a first direction; arrangements of interconnect structures at least partially within the socket region and coupling the word lines to sub-word line driver (SWD) devices of the control logic circuitry; an additional socket region horizontally neighboring the array region in a second direction orthogonal to the first direction; additional arrangements of interconnect structures at least partially within the additional socket region and coupling the digit lines to sense amplifier (SA) devices of the control logic circuitry; first global routing structures vertically above the control logic circuitry and confined within the horizontal area of the array region, the first global routing structures extending in parallel in the first direction; and second global routing structures vertically above the first global routing structures and continuously extending in parallel through the array region and the additional socket region in the second direction.

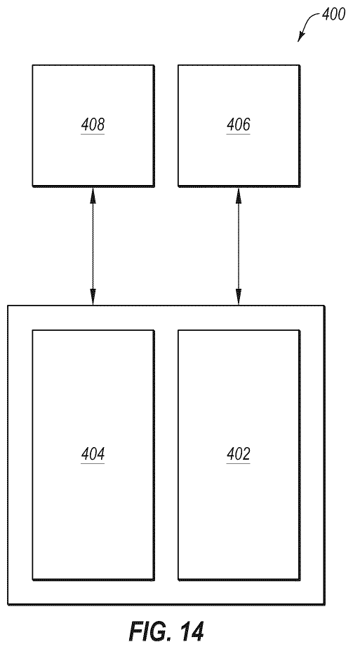

Microelectronic devices (e.g., the microelectronic devices 100, 100′) in accordance with embodiments of the disclosure may be used in embodiments of electronic systems of the disclosure. For example, FIG. 14 is a block diagram illustrating an electronic system 400 according to embodiments of disclosure. The electronic system 400 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 400 includes at least one memory device 402. The memory device 402 may comprise, for example, a microelectronic device (e.g., one of the microelectronic devices 100, 100′) previously described herein. The electronic system 400 may further include at least one electronic signal processor device 404 (often referred to as a “microprocessor”). The electronic signal processor device 404 may, optionally, comprise a microelectronic device (e.g., one of the microelectronic devices 100, 100′) previously described herein. While the memory device 402 and the electronic signal processor device 404 are depicted as two (2) separate devices in FIG. 14, in additional embodiments, a single (e.g., only one) memory/processor device having the functionalities of the memory device 402 and the electronic signal processor device 404 is included in the electronic system 400. In such embodiments, the memory/processor device may include a microelectronic device (e.g., one of the microelectronic devices 100, 100″) previously described herein. The electronic system 400 may further include one or more input devices 406 for inputting information into the electronic system 400 by a user, such as, for example, a mouse or other pointing device, a keyboard, a touchpad, a button, or a control panel. The electronic system 400 may further include one or more output devices 408 for outputting information (e.g., visual or audio output) to a user such as, for example, a monitor, a display, a printer, an audio output jack, a speaker, etc. In some embodiments, the input device 406 and the output device 408 comprise a single touchscreen device that can be used both to input information to the electronic system 400 and to output visual information to a user. The input device 406 and the output device 408 may communicate electrically with one or more of the memory device 402 and the electronic signal processor device 404.

Thus, in accordance with embodiments of the disclosure, an electronic system includes a processor device operably connected to an input device and an output device, and a memory device operably connected to the processor device. The memory device includes a memory array structure, a control circuitry structure, and global routing tiers. The memory array structure includes array regions having dynamic random-access memory (DRAM) cells therein. The DRAM cells respectively include an access device and a capacitor vertically overlying and coupled to the access device. The control circuitry structure vertically overlies and is bonded to the memory array structure. The control circuitry structure includes control circuitry regions horizontally overlapping the array regions of the memory array structure and having control logic circuitry coupled to the DRAM cells of the array regions. The global routing tiers vertically overlie the control logic circuitry of the control circuitry structure. The global routing tiers include a first global routing tier, a second global routing tier, and an additional global routing tier. The first global routing tier includes groups of main word line (MWL) routing structures confined within horizontal areas of the control circuitry regions of the control circuitry structure. The MWL routing structures of respective ones of the groups of the MWL routing structures horizontally extend in parallel in a first direction. The second global routing tier is vertically above the first global routing tier and includes groups of column select (CS) routing structures individually extending across and between multiple of the control circuitry regions of the control circuitry structure. The CS routing structures of respective ones of the groups of the MWL routing structures horizontally extend in parallel in a second direction orthogonal to the first direction. The additional global routing tier is vertically above the second global routing tier and includes groups of global input/output routing structures confined within the horizontal areas of the control circuitry regions of the control circuitry structure. The global input/output routing structures of respective ones of the groups of the global input/output routing structures horizontally extend in parallel in the first direction.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a memory array structure comprising array regions respectively including volatile memory cells;
a control circuitry structure vertically above and bonded to the memory array structure, the control circuitry structure comprising control circuitry regions horizontally overlapping the array regions and comprising control logic circuitry coupled to the volatile memory cells of the array regions; and
global routing tiers vertically overlying the control logic circuitry of the control circuitry structure,
some of the global routing tiers respectively comprising groups of global routing structures confined within horizontal areas of the control circuitry regions of the control circuitry structure, the global routing structures of respective ones of the groups horizontally extending in parallel in a first direction,
some others of the global routing tiers respectively comprising additional groups of global routing structures extending beyond the horizontal areas of the control circuitry regions of the control circuitry structure, the global routing structures of respective ones of the additional groups horizontally extending in parallel in a second direction orthogonal to the first direction.

2. The microelectronic device of claim 1, wherein the global routing tiers comprise:
a first global routing tier comprising groups of first global routing structures confined within the horizontal areas of the control circuitry regions, the first global routing structures of respective ones of the groups of first global routing structures extending in parallel in the first direction;
a second global routing tier vertically above the first global routing tier and comprising groups of second global routing structures extending beyond the horizontal areas of the control circuitry regions, the second global routing structures of respective ones of the groups of second global routing structures extending in parallel in the second direction;
a third global routing tier vertically above the second global routing tier and comprising groups of third global routing structures extending beyond the horizontal areas of the control circuitry regions, the third global routing structures of respective ones of the groups of third global routing structures extending in parallel in the second direction;
a fourth global routing tier vertically above third global routing tier and comprising groups of fourth global routing structures confined within the horizontal areas of the control circuitry regions, the fourth global routing structures of respective ones of the groups of fourth global routing structures extending in parallel in the first direction; and
a fifth global routing tier vertically above the fourth global routing tier and comprising groups of fifth global routing structures extending beyond the horizontal areas of the control circuitry regions, the fifth global routing structures of respective ones of the groups of fifth global routing structures extending in parallel in the second direction.

3. The microelectronic device of claim 2, wherein the first global routing tier further comprises:
additional groups of the first global routing structures outside of the horizontal areas of the control circuitry regions and alternating with the groups of the first global routing structures in the first direction, the first global routing structures of respective ones of the additional groups of the first global routing structures extending in parallel in the second direction; and
further groups of the first global routing structures outside of the horizontal areas of the control circuitry regions and alternating with the groups of the first global routing structures in the second direction, the first global routing structures of respective ones of the further groups of the first global routing structures extending in parallel in the first direction.

4. The microelectronic device of claim 3, wherein the second global routing tier further comprises additional groups of the second global routing structures respectively coupling two of the groups of first global routing structures of the first global routing tier to one another,
the additional groups of the second global routing structures alternating with the groups of the second global routing structures in the first direction, and
the second global routing structures of respective ones of the additional groups of the second global routing structures extending in parallel in the first direction.

5. The microelectronic device of claim 1, wherein:
the memory array structure further comprises:
word line exit regions horizontally alternating with the array regions in the first direction and comprising horizontal ends of word lines within horizontal areas thereof; and
digit line exit regions horizontally alternating with the array regions in the second direction and comprising horizontal ends of digit lines within horizontal areas thereof; and
the control circuitry structure further comprises:
word line contact regions horizontally alternating with the control circuitry regions in the first direction and horizontally overlapping the word line exit regions of the memory array structure; and
digit line contact regions horizontally alternating with the control circuitry regions in the second direction and horizontally overlapping the digit line exit regions of the memory array structure.

6. The microelectronic device of claim 5, wherein the control circuitry regions of the control circuitry structure respectively comprise:
sense amplifier (SA) sub-regions horizontally positioned diagonally opposite one another and individual comprising SA devices within a horizontal area thereof; and
sub-word line driver (SWD) sub-regions horizontally positioned diagonally opposite one another and individual comprising SWD devices within a horizontal area thereof.

7. The microelectronic device of claim 6, further comprising arrangements of conductive structures coupled to the volatile memory cells within the array regions of the memory array structure and the SA devices within the SA sub-regions of the control circuitry regions of the control circuitry structure, the arrangements of conductive structures extending through the digit line exit regions of the memory array structure and the digit line contact regions of the control circuitry structure.

8. The microelectronic device of claim 7, wherein the arrangements of conductive structures comprise:
first contact structures within the memory array structure and vertically above and coupled to the digit lines;
first routing structures within the memory array structure and vertically above and coupled to the first contact structures;
second contact structures within the memory array structure and vertically above and coupled to the first routing structures;
second routing structures within the memory array structure and vertically above and coupled to the second contact structures;
third contact structures partially extending through each of control circuitry structure and the memory array structure, the third contact structures vertically above and coupled to the second routing structures; and
third routing structures within the control circuitry structure and vertically above and coupled to the third contact structures.

9. The microelectronic device of claim 8, wherein:
the first contact structures, the first routing structures, the second contact structures, some of the second routing structures, some of the third contact structures, and some of the third routing structures are positioned within horizonal areas of the digit line exit regions of the memory array structure and the digit line contact regions of the control circuitry structure; and
some others of the second routing structures, some others of the third contact structures, some others of the third routing structures are positioned within horizonal areas of the SA sub-regions of the control circuitry regions of the control circuitry structure.

10. The microelectronic device of claim 8, further comprising:
additional contact structures within the memory array structure, the additional contact structures vertically above and coupled to the second routing structures; and
additional routing structures within the memory array structure, the additional routing structures vertically interposed between and coupled to the additional contact structures and the third contact structures.

11. The microelectronic device of claim 10, wherein:
the first contact structures, the first routing structures, the second contact structures, some of the second routing structures, some of the additional contact structures, some of the additional routing structures, some of the third contact structures, and some of the third routing structures are positioned within horizonal areas of the digit line exit regions of the memory array structure and the digit line contact regions of the control circuitry structure; and
some others of the second routing structures, some others of the additional contact structures, some others of the additional routing structures, some others of the third contact structures, some others of the third routing structures are positioned within horizonal areas of the SA sub-regions of the control circuitry regions of the control circuitry structure.

12. The microelectronic device of claim 5, wherein:
the digit line contact regions of the control circuitry structure comprise sense amplifier (SA) sub-regions within horizontal areas thereof, the SA sub-regions including SA devices coupled to the volatile memory cells within the array regions of the memory array structure; and
the word line contact regions of the control circuitry structure include sub-word line driver (SWD) sub-regions within horizontal areas thereof, the SWD sub-regions including SWD devices coupled to the volatile memory cells within the array regions of the memory array structure.

13. A memory device, comprising:
an array region comprising volatile memory cells, word lines coupled to the volatile memory cells, and digit lines coupled to the volatile memory cells;
control logic circuitry vertically above and at least partially horizontally overlapping the array region;
a socket region horizontally neighboring the array region in a first direction;
arrangements of interconnect structures at least partially within the socket region and coupling the word lines to sub-word line driver (SWD) devices of the control logic circuitry;
an additional socket region horizontally neighboring the array region in a second direction orthogonal to the first direction;
additional arrangements of interconnect structures at least partially within the additional socket region and coupling the digit lines to sense amplifier (SA) devices of the control logic circuitry;
first global routing structures vertically above the control logic circuitry and confined within a horizontal area of the array region, the first global routing structures extending in parallel in the first direction; and
second global routing structures vertically above the first global routing structures and continuously extending in parallel through the array region and the additional socket region in the second direction.

14. The memory device of claim 13, wherein the SWD devices and the SA devices of the control logic circuitry are substantially confined within the horizontal area of the array region.

15. The memory device of claim 14, wherein, for one of the SA devices, the additional arrangements of interconnect structures comprise:
a first additional arrangement of interconnect structures routing to a first side of the one of the SA devices; and
a second additional arrangement of interconnect structures routing to a second, opposing side of the one of the SA devices.

16. The memory device of claim 15, wherein at least one contact structure of the second additional arrangement is horizontally interposed, in the second direction, between the one of the SA devices and an additional one of the SA devices horizontally neighboring the one of the SA devices in the second direction.

17. The memory device of claim 16, wherein the at least one contact structure of the second additional arrangement comprises two contact structures vertically offset from and coupled to one another.

18. The memory device of claim 13, wherein:
the SWD devices of the control logic circuitry and the arrangements of interconnect structures are substantially confined within a horizontal area of the socket region; and
the SA devices of the control logic circuitry and the additional arrangements of interconnect structures are substantially confined within a horizontal area of the additional socket region.

19. The memory device of claim 18, further comprising:
first additional global routing structures at a vertical position of the first additional global routing structures and confined within the horizontal area of the additional socket region, the first additional global routing structures respectively configured for a different signal routing functionality than the first additional global routing structures and extending in parallel in the first direction; and
first further global routing structures at a vertical position of the first additional global routing structures and confined within the horizontal area of the socket region, the first further global routing structures respectively configured for a further, different signal routing functionality relative to the first global routing structures and extending in parallel in the second direction.

20. An electronic system, comprising:
a processor device operably connected to an input device and an output device; and
a memory device operably connected to the processor device and comprising:
a memory array structure including array regions having dynamic random-access memory (DRAM) cells therein, the DRAM cells respectively comprising an access device and a capacitor vertically overlying and coupled to the access device; and
a control circuitry structure vertically overlying and bonded to the memory array structure, the control circuitry structure comprising control circuitry regions horizontally overlapping the array regions of the memory array structure and having control logic circuitry coupled to the DRAM cells of the array regions; and
global routing tiers vertically overlying the control logic circuitry of the control circuitry structure and comprising:
a first global routing tier comprising groups of main word line (MWL) routing structures confined within horizontal areas of the control circuitry regions of the control circuitry structure, the MWL routing structures of respective ones of the groups of the MWL routing structures horizontally extending in parallel in a first direction;
a second global routing tier vertically above the first global routing tier and comprising groups of column select (CS) routing structures individually extending across and between multiple of the control circuitry regions of the control circuitry structure, the CS routing structures of respective ones of the groups of the MWL routing structures horizontally extending in parallel in a second direction orthogonal to the first direction; and
an additional global routing tier vertically above the second global routing tier and comprising groups of global input/output routing structures confined within the horizontal areas of the control circuitry regions of the control circuitry structure, the global input/output routing structures of respective ones of the groups of the global input/output routing structures horizontally extending in parallel in the first direction.
